(19) United States
(12) Patent Application Publication
(10) Pub. No.: US 2017/0218264 A1
(43) Pub. Date: Aug. 3, 2017

(54) LUMINESCENT SOLAR CONCENTRATORS COMPRISING SEMICONDUCTOR NANOCRYSTALS

(71) Applicants: Victor KLIMOV, Los Alamos, NM (US); Los Alamos National Security, LLC, Los Alamos, NM (US); Universita Degli Studi Di Milano-Bicocca, Milano (IT)

(72) Inventors: Victor I. Klimov, Los Alamos, NM (US); Hunter McDANIEL, Los Alamos, NM (US); Sergio BROVELLI, Milano (IT); Francesco MEINARDI, Lccco (IT)

(73) Assignees: Los Alamos National Security, LLC, Los Alamos, NM (US); Universita Degli Studi Di Milano-Bicocca, Milano (IT)

(21) Appl. No.: 15/519,023

(22) PCT Filed: Oct. 13, 2014
(86) PCT No.: PCT/US14/60303

§ 371 Date: Apr. 13, 2017

(51) Int. Cl. C09K 11/02; H01L 31/055; C09K 11/88; H01L 31/0384; H01L 31/0352; B82Y 30/00

(52) U.S. Cl. CPC C09K 11/02; H01L 31/035218; B82Y 30/00; C09K 11/025; C09K 11/883; H01L 31/0384; H01L 31/055; Y02E 10/52

(57) ABSTRACT

Disclosed herein are embodiments of a composition comprising a polymer or sol-gel matrix and one or more nanocrystals. The composition is useful for making various products, including a luminescent solar concentrator. The nanocrystals are dispersed in the polymer or sol-gel matrix to reduce or substantially prevent nanocrystal-to-nanocrystal energy transfer and a subsequent reduction in the emission efficiency of the composition. The nanocrystals may comprise an antenna portion and an emitter portion, and in some embodiments the materials for the antenna and emitter portions are selected to produce a large Stokes shift between the absorption and emission wavelengths. In some embodiments, the polymer matrix comprises an acrylate polymer. Also disclosed herein is a method for making the composition, which may comprise a pre-polymerization step before the nanocrystals are introduced. Devices comprising the composition and a photovoltaic cell also are disclosed. In some examples, the device is a window.

### CROSS REFERENCE TO RELATED APPLICATION

This is the U.S. National Stage of International Application No. PCT/US2014/060303, filed on Oct. 13, 2014, which was published in English under PCT Article 21(2), and is incorporated herein in its entirety.

### ACKNOWLEDGMENT OF GOVERNMENT SUPPORT

This invention was made with government support under Contract No. DE-AC52-06NA25396 awarded by the U.S. Department of Energy. The government has certain rights in the invention.

### FIELD

Certain disclosed embodiments concern a composition comprising semiconductor nanocrystals dispersed in a polymer matrix, and a device and method for using the composition, such as a luminescence solar concentrator.

### BACKGROUND

Semiconductor nanocrystals (NCs) are nanosized objects with dimensions typically smaller than 10-20 nm. NCs of various compositions and shapes are available, including nearly spherical quantum dots (QDs), elongated quasi-one-dimensional (1D) nanorods, quasi-2D nanoplatelets, as well as structures of more complex shapes such as tripods, tetrapods, hexapods, etc. NCs fabricated via colloidal chemistry have recently emerged as a novel platform for the realization of low-cost, solution-processed photovoltaics (PVs). The best reported efficiencies of NC-PVs quickly approach those of more mature bulk heterojunction solar cells based on organic materials. The current record certified efficiency of NC solar cells is close to 9%. In addition to being applied in all-NC PVs, colloidal nanocrystals also have been used to supplement more traditional PV materials as a means, for instance, to extend the spectral range of absorbed solar radiation. Such hybrid solar cells have been demonstrated, whereby the device spectral response was extended to near-infrared (down to about 1.2 μm) by combining PbS QDs with amorphous silicon.

An emerging application of NCs as “supplements” of more traditional PVs involves their use in low-cost, solution-processed luminescent solar concentrators (LSCs). LSCs are photon management devices that represent a cost-effective alternative to optics-based solar concentration systems.

### SUMMARY

Disclosed herein are embodiments of a substantially transparent composition. In particular disclosed embodiments, the substantially transparent composition comprises a polymer matrix and plural, substantially non-aggregated heterostructured nanocrystals substantially homogeneously dispersed in the polymer matrix and separated by a distance greater than an energy transfer distance. In certain particular embodiments the heterostructured nanocrystal comprise an antenna portion and an emitter portion. The size and/or formulation of the antenna portion and the size and/or formulation of the emitter portion may be selected to generate a desired global Stokes shift. In some embodiments, the hetero-interface between the antenna portion and the emitter portion is a type I, type II or quasi-type II interface. The antenna portion comprises an antenna material with a first band-gap, and the emitter portion comprises an emitter material with a second band-gap, and the first band-gap may be larger than the second band-gap.

In some embodiments, the NC have a geometry selected from a core/shell nanoparticle, hetero-nanorod, hetero-platelet, hetero-tripod, hetero-tetrapod, hetero-hexapod, dot-in-rod, dot-in-platelet, rod-in-rod, platelet-in-platelet, dot-in-bulk, complex branched hetero-structures, core/shell nanoplatelet, core/crown nanoplatelet or a combination thereof, and in certain examples, the nanocrystals comprise a core and at least one shell about the core having a shell thickness of greater than 0 to about 6 nanometers. The shell can comprise multiple shell layers, and/or can have a thickness of from about 3 to about 10 nanometers. In some embodiments the shell comprises from greater than zero to greater than 30 monolayers or shell layers, such as from about 5 to about 30 shell layers, with particular embodiments comprising 14 shell layers.

In some embodiments, the polymer matrix is a polymer matrix transparent to visible light, IR light, UV light, or a combination thereof. The polymer matrix can comprise any suitable polymer matrix now known or hereafter developed, with certain exemplary polymers being selected from poly acrylate, poly methacrylate, polyolefin, poly vinyl, epoxy resin, polycarbonate, polyacetate, polyamide, polyurethane, polyketone, polyester, polycyanoacrylate, silicone, polyglycol, polyimide, fluorinated polymer, polycellulose, poly oxazine or combinations thereof including statistical copolymers and block copolymers. In exemplary embodiments, the polymer matrix comprises an acrylate polymer. In some embodiments, the acrylate polymer is made from an acrylate monomer selected from methyl acrylate, ethyl acrylate, propyl acrylate, butyl acrylate, 2-chloroethyl acrylate, methyl methacrylate, ethyl methacrylate, butyl methacrylate, 2-ethylhexyl acrylate, hydroxyethyl methacrylate, trimethylolpropane triacrylate or a combination thereof. In particular disclosed embodiments, the acrylate polymer comprises polymethyl methacrylate.

The nanocrystal of the substantially transparent composition embodiments disclosed herein can comprise any suitable nanocrystal, with exemplary embodiments utilizing cadmium sulfide (CdS), cadmium selenide (CdSe), cadmium telluride (CdTe), zinc sulfide (ZnS), zinc selenide (ZnSe), zinc oxide (ZnO), zinc telluride (ZnTe), mercury sulfide (HgS), mercury selenide (HgSe), mercury telluride (HgTe), aluminum nitride (AlN), aluminum sulfide (AlS), aluminum phosphide (AlP), aluminum arsenide (AlAs), aluminum antimonide (AlSb), lead sulfide (PbS), lead selenide (PbSe), lead telluride (PbTe), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), zinc cadmium selenide (ZnCdSe), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN), Si, Ge, Sn, SiGe, SiSn, GeSn, gold (Au), silver (Ag), cobalt (Co), iron (Fe), nickel (Ni), copper (Cu), gallium, silicon, manganese (Mn) or combinations thereof. In particular disclosed embodiments, the nanocrystal comprises CdSe, CdS, CdTe, PbSe, PbS, PbTe, InAs, InSb, InP, Ge, Si, Sn, Sn, HgTe, HgSe, HgS, InN, AlN, GaN, ZnTe, ZnSe, ZnS, or ZnO or combinations thereof. The nanocrystal core can comprise CdSe, CdS, CdTe, PbSe, PbS, PbTe, InAs, InSb, InP, Ge, Si, Sn, Sn, HgTe, HgSe, HgS, InN, AlN, GaN, ZnTe, ZnSe, ZnS, or ZnO or combinations thereof. The nanocrystal shell can comprise CdSe, CdS, CdTe, PbSe, PbS, PbTe, InAs, InSb, InP, Ge, Si, Sn, Sn, HgTe, HgSe, HgS, InN, AlN, GaN, ZnTe, ZnSe, ZnS, or ZnO or combinations thereof. In some embodiments, the nanocrystal has a core/shell structure selected from CdSe/CdS, CdSe/ZnSe, CdSe/ZnS, CdSe/ZnTe, CdSe/CdTe, CdTe/CdSe, CdTe/CdS, CdTe/ZnSe, CdTe/ZnS, CdTe/ZnTe, CdS/ZnSe, CdS/ZnS, CdS/CdTe, CdS/CdSe, PbSe/PbS, PbS/PbSe, PbTe/PbS, PbS/PbTe, PbTe/PbSe, PbSe/PbTe, PbSe/CdSe, CdSe/PbTe, PbS/CdS, CdS/PbS, PbTe/CdTe, CdTe/PbTe, InAs/CdS, InSb/CdS, InP/CdS, InAs/CdSe, InSb/CdSe, InP/CdSe, InAs/ZnSe, InP/ZnSe, InSb/ZnSe, InAs/ZnS, InP/ZnS, InSb/ZnS, Ge/Si, Si/Ge, Sn/Si, Si/Sn, Ge/Sn, or Sn/Ge. In some examples, the nanocrystal is a quantum dot. Particular exemplary embodiments concern using a CdSe/CdS or PbSe/CdSe quantum dot. In some embodiments, the nanocrystal can be selected to have a global Stokes shift of greater than 200 meV. The concentration of the nanocrystals within the polymer matrix can be from greater than zero wt % to 10 wt % relative to the weight of the polymer matrix. In some embodiments, the nanocrystal concentration is from greater than zero wt % to 5 wt %, from greater than zero to 1% or from greater than zero to 0.5%. In exemplary embodiments, the nanocrystal concentration is from 0.01 wt % to 0.1 wt %.

Nanocrystals used in the disclosed substantially transparent composition can be dispersed in the polymer matrix such that a nanocrystal emission efficiency drops by less than 10% compared to a quantum dot emission efficiency of those same nanocrystals dissolved in a solvent. In other embodiments, the nanocrystal emission efficiency can drop by less than 5%. In yet other embodiments, the quantum dot emission efficiency can drop by less than 1%.

Particular embodiments disclosed herein concern a composition substantially transparent to visible light, infrared (IR) light, ultraviolet (UV) light, or a combination thereof. The composition comprises a polymer matrix wherein exemplary polymers are selected from poly acrylate, poly methacrylate, polyolefin, poly vinyl, epoxy resin, polycarbonate, polyacetate, polyamide, polyurethane, polyketone, polyester, polycyanoacrylate, silicone, polyglycol, polyimide, fluorinated polymer, polycellulose, poly oxazine or combinations thereof; and plural, substantially non-aggregated hetero-structured core/shell nanocrystals substantially homogeneously dispersed in the polymer matrix at a concentration of from greater than zero wt % to 10 wt % relative to the weight of the polymer matrix such that a nanocrystal emission efficiency drops by less than 10% compared to a nanocrystal emission efficiency of those same quantum dots dissolved in a solvent. For certain embodiments, the core/shell structure is selected from CdSe/CdS, CdSe/ZnSe, CdSe/ZnS, CdSe/ZnTe, CdSe/CdTe, CdTe/CdSe, CdTe/CdS, CdTe/ZnSe, CdTe/ZnS, CdTe/ZnTe, CdS/ZnSe, CdS/ZnS, CdS/CdTe, CdS/CdSe, PbSe/PbS, PbS/PbSe, PbTe/PbS, PbS/PbTe, PbTe/PbSe, PbSe/PbTe, PbSe/CdSe, CdSe/PbTe, PbS/CdS, CdS/PbS, PbTe/CdTe, CdTe/PbTe, InAs/CdS, InSb/CdS, InP/CdS, InAs/CdSe, InSb/CdSe, InP/CdSe, InAs/ZnSe, InP/ZnSe, InSb/ZnSe, InAs/ZnS, InP/ZnS, InSb/ZnS, Ge/Si, Si/Ge, Sn/Si, Si/Sn, Ge/Sn, or Sn/Ge, the nanocrystals comprising from 5 to about 30 shell layers and having a shell thickness of from about 3 to about 6 nanometers. Typically the nanocrystals have a global Stokes shift of greater than 200 meV and are separated by a distance greater than an energy transfer distance.

Also disclosed herein are embodiments of a device comprising disclosed composition embodiments. In particular embodiments, the nanocrystals dispersed in the polymer matrix have a quantum yield of from greater than 0 to 90%. In some embodiments, the quantum yield ranges from 10% to 80% and in other embodiments can range from 10% to 50%. The polymer matrix of the device can be a polymer matrix transparent or semi-transparent to visible light, infrared light, ultraviolet light or a combination thereof.

Particular disclosed device embodiments can further comprise a photovoltaic cell. In some embodiments, the device can further comprise a reflector and/or a diffuser. In particular disclosed embodiments, the device is a window. The window can comprise at least one window pane comprising the composition. In other embodiments, the window can comprise at least one window pane at least partially coated with a film comprising the composition. The window also can comprise at least two window panes wherein the composition is positioned between the window panes. In some embodiments, the device is an optical fiber. The composition also can be formulated as a viscous fluid. These composition embodiments have a variety of applications, such as transparent packaging material.

Also disclosed herein are embodiments of a building or transportation device having at least one window. The window in the building or transportation device comprises a composition as disclosed herein. In some embodiments, the transportation device is an automobile, ship or airplane.

Embodiments of a method for making disclosed compositions also are provided. In some embodiments, the method comprises dispersing core/shell quantum dots or other types of hetero-structured nanocrystals in a first amount of a monomer comprising a first polymerization initiator to form a dispersion of quantum dots in the monomer; heating a second amount of the monomer with a second polymerization initiator at a first temperature to initiate polymerization of the second amount of monomer; quenching the polymerization of the second amount of monomer, before the polymerization proceeds to completion, to form a partially polymerized mixture; mixing the partially polymerized mixture with the dispersion of quantum dots in monomer to form a second mixture; and heating the second mixture at a second temperature to form the composition comprising a polymer matrix with quantum dots dispersed within.

In certain embodiments of the method, the polymer matrix comprises a polymer selected from poly acrylate, poly methacrylate, polyolefin, poly vinyl, epoxy resin, polycarbonate, polyacetate, polyamide, polyurethane, polyketone, polyester, polycyanoacrylate, silicone, polyglycol, polyimide, fluorinated polymer, polycellulose, poly oxazine or combinations thereof. In exemplary embodiments of the method, the monomer is an acrylate monomer. The acrylate monomer can be selected from methyl acrylate, ethyl acrylate, propyl acrylate, butyl acrylate, 2-chloroethyl acrylate, methyl methacrylate, ethyl methacrylate, butyl methacrylate, 2-ethylhexyl acrylate, hydroxyethyl methacrylate, trimethylolpropane triacrylate or a combination thereof. In some embodiments, the acrylate monomer comprises methyl methacrylate.

The first polymerization initiator and second polymerization initiator can be any suitable initiator, with certain embodiments independently being selected from a peroxide, azo compound, persulfate or organometallic compound. In some embodiments, the first polymerization initiator and the second polymerization initiator are independently lauroyl peroxide, di-tert-butyl peroxide, benzoyl peroxide, methyl ethyl ketone peroxide, tert-butyl peracetate, tert-butyl hydroperoxide, acetone peroxide, azobisisobutyronitrile (AIBN), 1,1′-azobis(cyclohexanecarbonitrile) (ABCN), 4,4′-azobis(4-cyanovaleric acid) (ABVA), potassium persulfate, triethylaluminum, titanium tetrachloride or a combination thereof. In other embodiments, the first polymerization initiator and the second polymerization initiator are different. The first polymerization initiator typically has an activation temperature greater than the activation temperature of the second polymerization initiator. In particular exemplary embodiments, the first polymerization initiator is lauroyl peroxide and the second polymerization initiator is AIBN. In some embodiments of the method, the first temperature is from greater than 25° C. to 150° C., or from 70° C. to 100° C., or from 80° C. to 85° C. The second temperature is from 25° C. to 150° C. in some embodiments, but also can range from 50° C. to 100° C. or from 50° C. to 60° C. in some embodiments. The first temperature can be greater than the second temperature in certain embodiments.

Quenching the polymerization of the second amount of monomer can comprise cooling the second amount of monomer to a third temperature sufficient to slow down or substantially stop the polymerization reaction. The third temperature can range from greater than 0° C. to less than 70° C., or less than or equal to 55° C. The method also can comprise post-curing the polymer matrix at a post-curing temperature. The post-curing temperature can range from 50° C. to 150° C. In some embodiments, post-curing the polymer matrix comprises heating the polymer matrix at from 100° C. to 125° C. for a post-curing period of from about 12 hours to about 18 hours.

Further disclosed herein are embodiments of a product made by any of the method embodiments disclosed herein. The product can be a window, such as in a building or transportation device.

The foregoing and other objects, features, and advantages of the invention will become more apparent from the following detailed description, which proceeds with reference to the accompanying figures.

### BRIEF DESCRIPTION OF THE DRAWINGS

FIG. 1 is a schematic diagram of an exemplary luminescent solar concentrator.

FIG. 2 is band diagram of CdSe/CdS core/shell QDs showing rapid transfer of photogenerated holes from the shell to the core (arrow 1) following photon absorption in the shell (arrow 2), with arrow 3 showing radiative recombination of a core-localized exciton.

FIG. 3 is a schematic diagram illustrating the structure of electronic states in an exemplary PbSe/CdSe QD.

FIG. 4 is a graph of absorption and photoluminescence versus photon energy, illustrating the absorption and emission of core/shell PbSe/CdSe QDs.

FIG. 5 is a schematic diagram illustrating some exemplary alternative geometries of hetero-structured nanocrystals.

FIG. 6 is a schematic diagram illustrating four different types of hetero-structures that can provide a large Stokes shift between absorption and emission.

FIG. 7 is a schematic diagram of an alternative embodiment of a luminescent solar concentrator.

FIG. 8 is a schematic cross-sectional view of a photovoltaic cell.

FIG. 9 is a schematic cross-sectional view of one configuration of a photovoltaic cell with a substrate configuration.

FIG. 10 is a schematic cross-sectional view of one configuration of a photovoltaic cell with a superstrate configuration.

FIG. 11 is a schematic cross-sectional view of a device comprising a slab and a film coating comprising a composition disclosed herein.

FIG. 12 a schematic cross-sectional view of a device comprising a composition as disclosed herein positioned between two substantially planar substrates.

FIG. 13 provides transmission electron microscopy (TEM) images of core/shell PbSe/CdSe quantum dots with the same overall radius and different shell thicknesses.

FIG. 14 is a ¹H NMR spectrum of the PMMA matrix, with the “*” symbols indicating the presence and amount of the methylene protons relative to the presence of unreacted monomer in the bulk polymer.

FIG. 15 is a differential scanning calorimetry (DSC) curve (second heating ramp) of a PMMA plate showing a glass transition temperature of about 117° C., comparable to industrial grade PMMA.

FIG. 16 is a graph of counts versus time, illustrating the gel permeation chromatography (GPC) measurements of the PMMA matrix.

FIG. 17 is a graph of absorption and photoluminescence versus wavelength, illustrating the optical absorption (dashed lines) and photoluminescence (PL, solid lines) spectra of reference core-only CdSe QDs with radius R₀=1.5 nm (4) and CdSe/CdS giant-QDs (5) having the same core radius and shell thickness H=5 nm.

FIG. 18 is a graph of PL intensity versus wavelength, illustrating the simulation of the evolution PL spectra of CdSe QDs and CdSe/CdS core-shell QDs as a function of distance, d (up to one meter), between the excitation and the detection points conducted using the experimentally measured spectra from FIG. 17.

FIG. 19 is a graph of normalized PL intensity versus optical path, illustrating the integrated intensity as a function of d for the two materials from FIG. 18, with the absorption coefficients normalized at 500 nm.

FIG. 20 is a schematic diagram illustrating a Monte Carlo ray tracing simulation for an LSC device comprising a reference core-only CdSe (R₀=1.5 nm, emission quantum yield Φ=4%).

FIG. 21 is a schematic diagram illustrating a Monte Carlo ray tracing simulation for an LSC device comprising a core/shell CdSe/CdS QDs (R₀=1.5 nm, H=5 nm, and Φ=45%).

FIG. 22 is a graph of output probability versus optical distance, illustrating the probability for a photon emitted at a certain distance from the slab edge to reach the PV in LSCs comprising reference core-only CdSe QDs from FIG. 20 (circles) and core/shell CdSe/CdS QDs from FIG. 21 (triangles), and the same calculations but assuming a 100% PL quantum yield for both samples illustrated by squares (CdSe QDs) and diamonds (CdSe/CdS QDs).

FIG. 23 is a schematic diagram illustrating Monte Carlo ray tracing simulations for LSC devices comprising core-only CdSe (R₀=1.5 nm) and core/shell CdSe/CdS QDs (R₀=1.5 nm; H=4.2 nm), with both samples having the ideal PL quantum yield of 100%.

FIG. 24 is a graph of absorption and photoluminescence versus wavelength, illustrating the absorption (shading) and photoluminescence spectra (no shading) of hexane solutions (solid lines) and PMMA compositions (dashed lines) of CdSe/CdS QDs with increasing H (0, 0.6, 1.5, 2.7 and 4.2 nm from bottom to top), and with the corresponding shell thicknesses in terms of the number of CdS monolayers (MLs) reported next to each curve.

FIG. 25 is a graph of absorption cross section versus shell thickness, illustrating the absorption cross section at 480 nm for CdSe/CdS QDs with R₀=1.5 nm and increasing shell thickness H=2, 5, 9 and 14 ML.

FIG. 26 is a graph of photoluminescence quantum yields versus shell thickness, illustrating the PL quantum yields of QD hexane solutions (Φ_{SOL}, circles) and PMMA nanocomposites (Φ_{PMMA}, triangles) measured under weak steady state excitation at 473 nm plotted as a function of (R₀+H).

FIG. 27 is a graph of photoluminescence quenching factor versus shell thickness, illustrating the PL quenching factor, Θ_{PL}=(Φ_{HEX}−Φ_{PMMA})/Φ_{HEX}, plotted as a function of (R₀+H).

FIG. 28 is a graph of normalized photoluminescence intensity versus time, illustrating the room-temperature photoluminescence decay of a QD hexane solutions (circles) and QD-PMMA nanocomposites (triangles) comprising CdSe/CdS QDs with R₀=1.5 nm and H=14 ML.

FIG. 29 is a graph of normalized photoluminescence intensity versus time, illustrating the room-temperature photoluminescence decay of a QD hexane solutions (circles) and QD-PMMA nanocomposites (triangles) comprising CdSe/CdS QDs with R₀=1.5 nm and H=0 ML.

FIG. 30 is a graph of normalized photoluminescence intensity versus time, illustrating the room-temperature photoluminescence decay of a QD hexane solutions (circles) and QD-PMMA nanocomposites (triangles) comprising CdSe/CdS QDs with R₀=1.5 nm and H=5 ML.

FIG. 31 is a graph of normalized PL intensity versus time, illustrating the room temperature PL decays of PMMA nanocomposites of CdSe/CdS QDs with R₀=1.5 nm and H=2 ML and H=14 ML under weak excitation at 405 nm synthesized in air and argon atmosphere.

FIG. 32 is a digital image of a QD-PMMA-based LSC (dimensions: 21.5 cm×1.35 cm×0.5 cm) comprising CdSe/CdS QDs (R₀=1.5 and H=4.2 nm) under ambient illumination.

FIG. 33 is a digital image of a QD-PMMA-based LSC (dimensions: 21.5 cm×1.35 cm×0.5 cm) comprising CdSe/CdS QDs (R₀=1.5 and H=4.2 nm) illuminated by an ultraviolet lamp emitting at 365 nm.

FIG. 34 is a graph of absorbance and normalized photoluminescence versus wavelength, illustrating the optical absorption spectra of the QD hexane solution (dotted line) and the QD-PMMA composite from FIGS. 31 and 32 (solid line) showing a minimal contribution from scattering, and normalized photoluminescence spectra (excitation at 473 nm) collected at the edge of the LSC when the excitation spot is located at distances d=0 cm or d=20 cm from the edge.

FIG. 35 is a graph of photoluminescence output versus optical path, illustrating spectrally integrated photoluminescence intensity as a function of d (circles; derived from data in FIG. 34) in comparison to the intensity of scattered 835 nm light (triangles).

FIG. 36 is a graph of absorbance and normalized PL intensity versus wavelength, illustrating the optical absorption and PL spectra collected at the edge of the LSC as a function of the distance, d, between the excitation spot and the slab edge for a PMMA LSC based on core-only CdSe QDs.

FIG. 37 is a graph of normalized integrated PL intensity and guided light versus optical path, illustrating the spectrally integrated PL intensity for a PMMA LSC based on core-only CdSe QDs as a function of d (circles; derived from data in FIG. 36) in comparison to the intensity of scattered 700 nm light (triangles), and including the PL intensity corrected for scattering losses (squares).

FIG. 38 is a graph of normalized PL intensity and absorption versus wavelength, illustrating the optical absorption and PL spectra collected at the edge of the LSC as a function of the distance, d, between the excitation spot and the slab edge for a PMMA-LSC based on the organic dye BASF Lumogen R305.

FIG. 39 is a graph of normalized integrated PL intensity and guided light versus optical path, illustrating the spectrally integrated PL intensity as a function of d (circles; derived from data in FIG. 38) in comparison to the intensity of scattered 700 nm light (squares) for a PMMA-LSC based on the organic dye BASF Lumogen R305.

FIG. 40 is a photograph of the LSC from FIGS. 32 and 33 during measurement of the concentration factor with illumination from a solar simulator (1.5 AM global).

### DETAILED DESCRIPTION

### I. Definitions

The following explanations of terms and methods are provided to better describe the present disclosure and to guide those of ordinary skill in the art in the practice of the present disclosure. The singular forms “a,” “an,” and “the” refer to one or more than one, unless the context clearly dictates otherwise. The term “or” refers to a single element of stated alternative elements or a combination of two or more elements, unless the context clearly indicates otherwise. As used herein, “comprises” means “includes.” Thus, “comprising A or B,” means “including A, B, or A and B,” without excluding additional elements. All references, including patents and patent applications cited herein, are incorporated by reference.

Unless otherwise indicated, all numbers expressing quantities of components, molecular weights, percentages, temperatures, times, and so forth, as used in the specification or claims are to be understood as being modified by the term “about.” Accordingly, unless otherwise indicated, implicitly or explicitly, the numerical parameters set forth are approximations that may depend on the desired properties sought and/or limits of detection under standard test conditions/methods. When directly and explicitly distinguishing embodiments from discussed prior art, the embodiment numbers are not approximates unless the word “about” is recited.

Unless explained otherwise, all technical and scientific terms used herein have the same meaning as commonly understood to one of ordinary skill in the art to which this disclosure belongs. Although methods and materials similar or equivalent to those described herein can be used in the practice or testing of the present disclosure, suitable methods and materials are described below. The materials, methods, and examples are illustrative only and not intended to be limiting.

As used herein, “alkyl” refers to a straight (i.e., unbranched), branched or cyclic saturated hydrocarbon chain. Unless expressly stated otherwise, an alkyl group contains from one to at least twenty-five carbon atoms (C₁-C₂₅); for example, from one to fifteen (C₁-C₁₅), from one to ten (C₁-C₁₀), from one to six (C₁-C₆), or from one to four (C₁-C₄) carbon atoms. A cycloalkyl contains from three to at least twenty-five carbon atoms (C₁-C₂₅); for example, from three to fifteen (C₁-C₁₅), from three to ten (C₁-C₁₀), from three to six (C₁-C₆). The term “lower alkyl” refers to an alkyl group comprising from one to ten carbon atoms or three to ten for a cycloalkyl. Unless expressly referred to as “unsubstituted alkyl,” an alkyl group can either be substituted or unsubstituted. Examples of alkyl groups include, but are not limited to, groups such as methyl, ethyl, n-propyl, isopropyl, n-butyl, t-butyl, isobutyl, sec-butyl, homologs and isomers of, for example, n-pentyl, n-hexyl, n-heptyl, n-octyl, and the like. Examples of cycloalkyl groups include, but are not limited to, cyclopropyl, cyclobutyl, cyclopentyl, cyclohexyl and the like.

### II. Overview

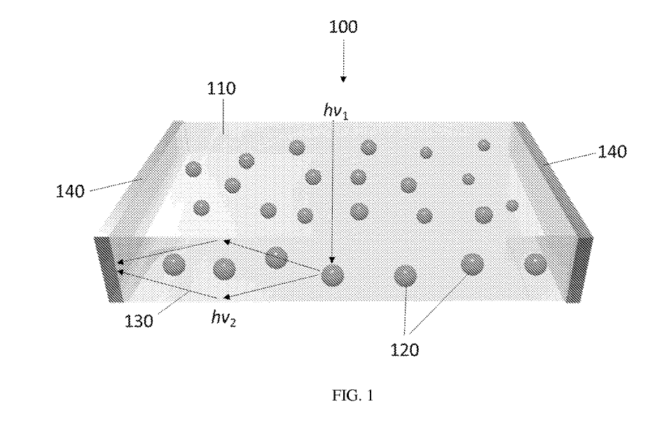

FIG. 1 shows a schematic diagram of a typical luminescent solar concentrator (LSC) 100, comprising an optical waveguide 110 comprising a polymer matrix doped with fluorophores 120 (usually luminescent dyes or NCs) or glass substrates coated with active layers of emissive materials. Direct as well as diffused sunlight (hv₁), which penetrates the matrix, is absorbed by the fluorophores and then re-emitted at a longer wavelength (hv₂). The luminescence 130, guided by total internal reflection, propagates towards a photovoltaic (PV) cell 140 positioned as desired to receive the luminescence, such as at the edge of the waveguide, where it is converted into electricity. Since the LSC area exposed to sunlight can be much greater than the area of the PV itself, the use of this approach can, in principle, greatly increase the flux of radiation incident onto the device and thus boost both the photocurrent and the photovoltage. An additional increase in the power output can be obtained by matching the emission wavelength of LSC emitters to the spectral peak of the PV efficiency of a given device.

Colloidal NCs, such as QDs, nanorods, or semiconductor particles of other shapes, are promising materials for application in LSCs. They feature high, near-unity emission efficiency, large absorption cross-sections and a tunable emission wavelength controlled by the NC size. Furthermore, colloidal NCs show enhanced photostability over organic chromophores, typically used in LSCs, and can be incorporated into various organic and inorganic matrices via solution-based procedures. One challenge, however, for using conventional NCs in LCS is a fairly small energy separation between the emission line and the band-edge absorption peak. In the colloidal NC literature this separation is usually referred to as a “global” Stokes shift, in contrast to a smaller “true” Stokes shift observed using size-selective techniques, such as fluorescence line narrowing.

In colloidal NCs a global Stokes shift arises from the combination of effects of band-edge fine-structure splitting (due, e.g., to shape anisotropy, electron-hole exchange interactions and crystal field), phonon-assisted emission and size polydispersity. In standard core-only CdSe QDs, it is typically on the order of a few tens of meV, which is comparable to the photoluminescence (PL) bandwidth. As a result of a significant overlap between absorption and PL spectra, light emitted by the QDs can experience significant re-absorption, which becomes an especially serious problem in the case of long optical pathways, which are expected in large area LSCs. While a certain fraction of absorbed light is re-emitted, the net result is still an overall emission loss because of both a non-unity PL quantum yield (Φ) and the isotropic character of emitted radiation, which does not allow for efficient capture of all re-reradiated photons by total internal reflection. For example, in a typical glass or polymer waveguide with refractive index n of 1.5-1.6, only about 75% of the emitted light is retained by total internal reflection, while the rest escapes from the waveguide.

Several strategies have been proposed to artificially increase the Stokes shift in NC materials. One approach involves NC doping with optically active metal ions such as Mn, Cu, or Ag. Light absorption of doped QDs is dominated by a semiconductor host, while emission is mediated by intra-gap states introduced by metal impurities. As a result, such structures can exhibit very large Stokes shifts up to a few hundreds of meV. The PL efficiency of doped NCs, however, is typically low (about 20-30%) because of very slow radiative recombination (hundreds of ns to microseconds lifetimes), which can be easily outcompeted by various non-radiative processes, such as trapping at surface defects. Furthermore, slow radiative dynamics impose an intrinsic limit on a maximum emission rate of a given fluorophore, which can limit the efficiency of light concentration if the radiative rate becomes lower than the photon absorption rate.

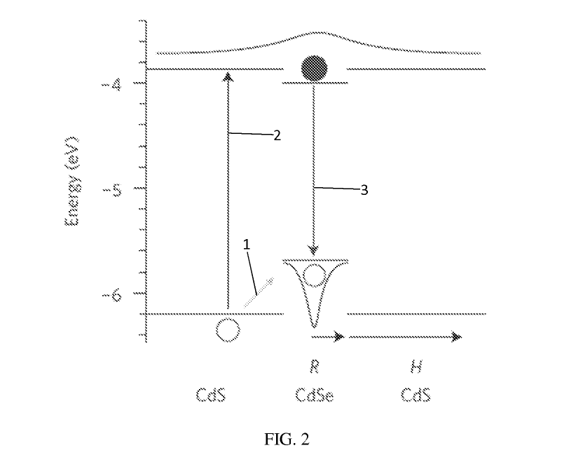

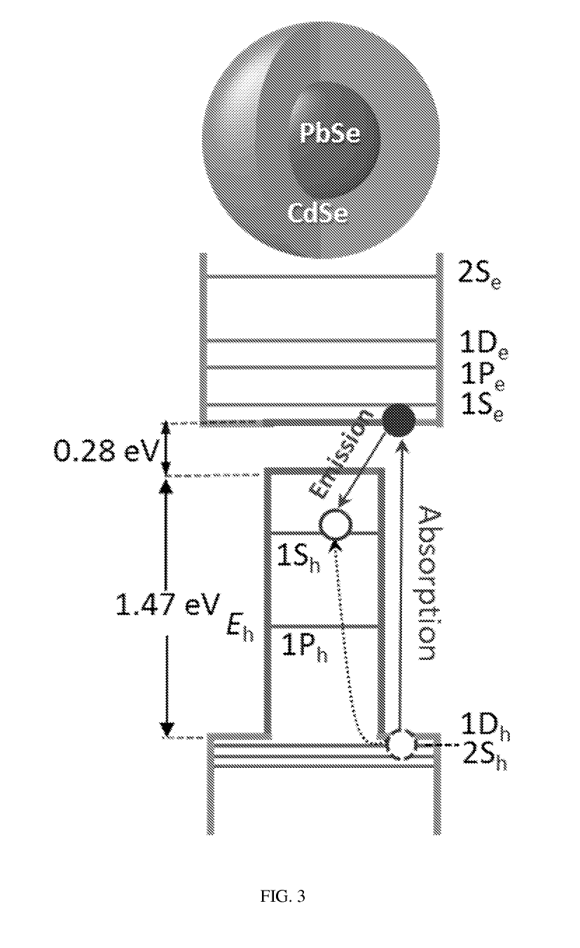

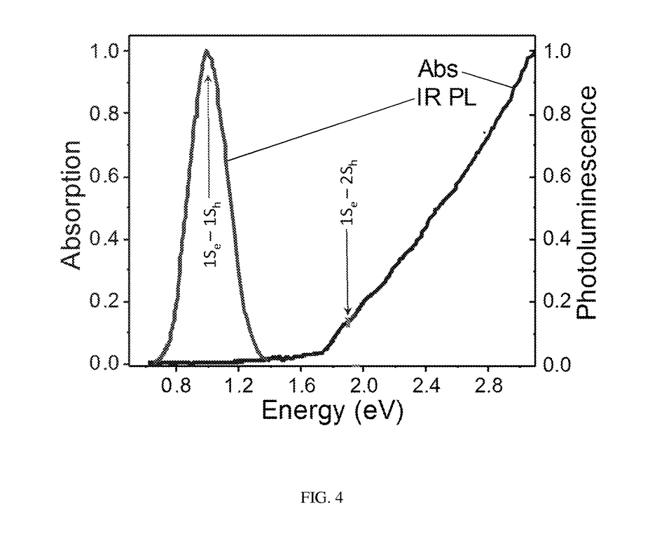

A promising approach to Stokes-shift engineering involves using heterostructured NCs. In an appropriately designed hetero-NC, the energy separation between the absorption and emission spectra can be artificially increased by separating light absorption and emission functions between two distinct parts of the nanostructure: with one serving as an efficient light-harvesting antenna; the other as a lower-energy emitter. Such behavior can be realized, for example, using quasi-type II core/shell CdSe/CdS or PbSe/CdSe QDs with an especially thick shell (so-called giant or g-QDs or dot-in-bulk nanocrystals in the case of extremely thick shells). Because of a small energy offset between the conduction band edges of CdSe and CdS, or PbSe, the electron wave function is delocalized over the entire QD volume, while the hole is tightly confined to the CdSe core (FIG. 2). Due to extremely rapid transfer of holes from the CdS shell to the CdSe core (<1 ps), emission from these systems is normally dominated by recombination of core excitons while light absorption is primarily due to a much-larger CdS shell. FIG. 3 illustrates an exemplary core/shell PbSe/CdSe QD system. With reference to FIG. 3, light absorption is dominated by the CdSe shell, while light emission occurs from the PbSe core. The band gap of CdSe (1.75 eV) is much larger than the band gap of PbSe (0.28 eV), which leads to a large effective Stokes shift between the emission spectrum and the onset of strong optical absorption (see FIG. 4). This greatly reduces light losses due to reabsorption. FIG. 4 provides an example of absorption and emission spectra of core/shell PbSe/CdSe QDs with an overall radius R=4 nm and shell thicknesses H=2.56 nm. These spectra illustrate a “giant” Stokes shift achievable with these structures. The PL peak is at 0.9 eV and the onset of strong absorption is at 1.75 eV. This indicates the effective Stokes shift of 850 meV. Arrows mark optical transitions responsible for emission and absorption (see FIG. 3 for assignment of electronic states).

A similar separation between light emission and absorption functions is provided by quantum dot systems, such as CdSe/CdS or PbSe/CdSe systems, of other geometries including dot-in-rod, dot-in-platelet, rod-in-rod and platelet-in-platelet structures, as well as hetero-tetrapods. However, several important features of thick-shell g-QDs make them more suitable candidates for LSC applications compared to other types of CdSe/CdS nanostructures. One such feature is a nearly complete isolation of the emitting core from the environment by a thick outer shell. This reduces carrier losses due to non-radiative recombination via surface defects and greatly improves the ability of QDs to retain their light emitting properties during various types of thermal and/or chemical treatments, including those applied for incorporation of QDs into sol-gel or polymer matrices. In addition, a thick shell reduces the strength of inter-dot, dipole-dipole coupling, which suppresses dot-to-dot energy transfer. As incorporation of QDs into matrices often results in their aggregation, if not eliminated, inter-dot energy transfer might become a source of additional non-radiative losses as it would allow for an exciton to sample centers of non-radiative recombination in not just one but multiple QDs within the energy transfer distance. Further, g-QDs feature reduced rates of non-radiative Auger recombination whereby an exciton decays without emitting a photon and instead transfers its energy to a charge carrier residing in the same QD. Such additional charges can be created, for example, at high excitation intensities via absorption of multiple photons. Due to a fairly low flux characteristic of solar radiation, this process is unlikely in LSCs. On the other hand, a prolonged exposure of QDs to sunlight may result in their photocharging via either direct escape of one of the photogenerated carriers from the dot or Auger-ionization. In the case of standard QDs, an exciton generated in a charged particle decays predominantly via fast Auger recombination, which can greatly reduce the LSC efficiency. On the other hand, because of suppressed Auger decay, the g-QDs exhibit fairly high emission efficiencies for both neutral and charged multi-carrier states, which at least partially alleviates the problem of photocharging that might occur in LSCs.

### III. Compositions

Disclosed herein are embodiments of a composition comprising a polymer matrix and a plurality of semiconductor nanocrystals (NCs). In some embodiments, the composition is at least partially transparent to light, such as visible light, infrared (IR) light, ultraviolet (UV) light or combinations thereof, and may be substantially completely transparent to light.

A. Semiconductor Nanocrystals

Semiconductor nanocrystals are crystalline particles that are sufficiently small to exhibit quantum mechanical properties. The nanocrystals may comprise more than one semiconductor material. In some embodiments, the nanocrystals are colloidal nanocrystals. The nanocrystals may comprise a core and one or more shells enclosing the core. The core and one or more shells may be made from the same or different materials. In certain embodiments, the nanocrystals comprise a core comprising a core material and a shell comprising a shell material. In some examples, the quantum dots further comprise at least a second shell comprising the same shell material or a second shell material. The core and shell(s) materials can be selected to produce quantum dots with specifically desired properties, such as a global Stokes-shift in a particular desired range, such as greater than 100 meV, or greater than 200 meV.

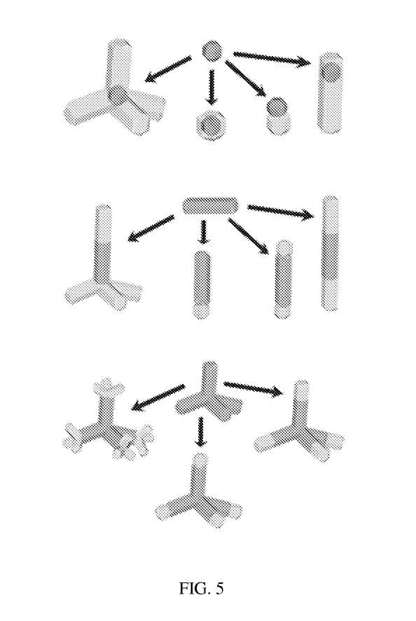

In some embodiments, the nanocrystals are substantially spherical and in this case are often referred to as quantum dots, such as core/shell quantum dots. In other embodiments, the nanocrystals have different shapes, such as rods, tetrapods, hetero-nanorod, hetero-platelet, hetero-tripod, hetero-tetrapod, hetero-hexapod, dot-in-rod, dot-in-platelet, rod-in-rod and platelet-in-platelet, dot-in-bulk, complex branched hetero-structures or more complex geometries (see FIG. 5 for some exemplary geometries). Further information regarding other possible geometries for heterostructured quantum dots is provided by C. d. M. Donega, Synthesis and properties of colloidal heteronanocrystals, Chemical Society Reviews, 2011, 40:1512-1546, which is incorporated herein by reference.

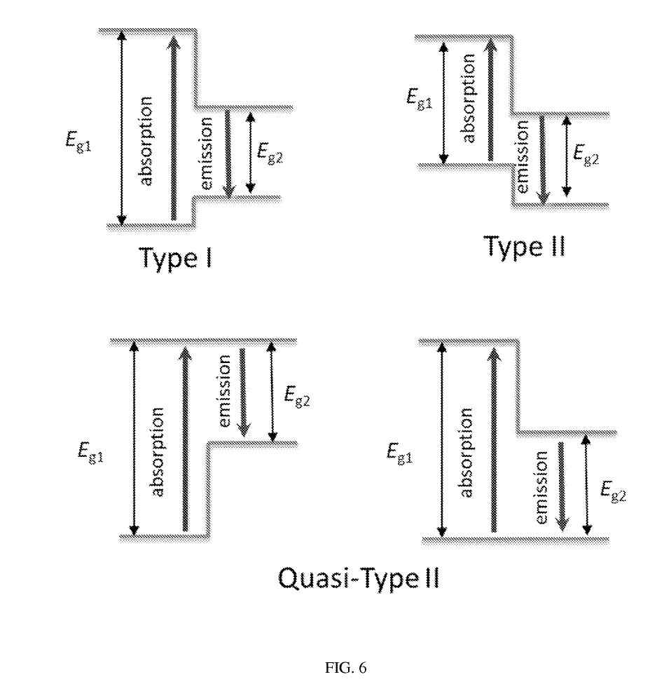

Nanocrystals suitable for use in the present technology typically comprise at least two materials. One material is used as a light absorbing antenna, and the other material is a light emitter. The light absorbing material typically has an energy band gap (E_{g1}) wider than the band gap of the light emitting material (E_{g2}). This difference in the band gaps of the materials, with E_{g1}>E_{g2}, leads to the “giant” Stokes shift between the absorption and emission wavelengths (FIG. 6).

In some embodiments, the colloidal nanocrystals include a core of a binary semiconductor material, e.g., a core of the formula MX, where: M may be cadmium, zinc, mercury, aluminum, lead, tin, gallium, indium, thallium, magnesium, calcium, strontium, barium, copper, and mixtures or alloys thereof; and X is sulfur, selenium, tellurium, nitrogen, phosphorus, arsenic, antimony, and mixtures or alloys thereof. In other embodiments, the colloidal quantum dots include a core of a ternary semiconductor material, e.g., a core of the formula M₁M₂X, where: M₁ and M₂ may be cadmium, zinc, mercury, aluminum, lead, tin, gallium, indium, thallium, magnesium, calcium, strontium, barium, copper, and mixtures or alloys thereof; and X is sulfur, selenium, tellurium, nitrogen, phosphorus, arsenic, antimony, and mixtures or alloys thereof. In alternative embodiments, the colloidal quantum dots include a core of a quaternary semiconductor material, e.g., a core of the formula M₁M₂M₃X, where: M₁, M₂ and M₃ may be cadmium, zinc, mercury, aluminum, lead, tin, gallium, indium, thallium, magnesium, calcium, strontium, barium, copper, and mixtures or alloys thereof; and X is sulfur, selenium, tellurium, nitrogen, phosphorus, arsenic, antimony, and mixtures or alloys thereof. In other examples, the colloidal quantum dots include a core of a quaternary semiconductor material, e.g., a core of a formula such as M₁X₁X₂, M₁M₂X₁X₂, M₁M₂M₃X₁X₂, M₁X₁X₂X₃, M₁M₂X₁X₂X₃ or M₁M₂M₃X₁X₂X₃, where: M₁, M₂ and M₃ may be cadmium, zinc, mercury, aluminum, lead, tin, gallium, indium, thallium, magnesium, calcium, strontium, barium, copper, and mixtures or alloys thereof; and X₁, X₂ and X₃ may be sulfur, selenium, tellurium, nitrogen, phosphorus, arsenic, antimony, and mixtures or alloys thereof. Examples include cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum sulfide (AlS), aluminum phosphide (AlP), aluminum arsenide (AlAs), aluminum antimonide (AlSb), lead sulfide (PbS), lead selenide (PbSe), lead telluride (PbTe), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), zinc cadmium selenide (ZnCdSe), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN) and the like, mixtures of such materials, or any other semiconductor or similar materials. The colloidal nanocrystal cores may be of silicon (Si), germanium (Ge), tin (Sn), and alloys thereof (e.g., SnₓSi₁₋ₓ, SnₓGe₁₋ₓ, or GeₓSi₁₋ₓ, where x is from greater than 0 to less than 1) or may be oxides such as zinc oxide (ZnO), titanium oxide (TiO₂), silicon oxide (SiO₂), aluminum oxide (Al₂O₃), or zirconium oxide (ZrO₂) and the like. In another embodiment, the colloidal nanocrystal include a core of a metallic material, such as gold (Au), silver (Ag), cobalt (Co), iron (Fe), nickel (Ni), copper (Cu), manganese (Mn), alloys thereof and alloy combinations.

Additionally, the nanocrystals comprise one or more shells about the core. The shells can also be a semiconductor material, and may have a composition different than the composition of the core. The shells can include materials selected from among Group II-VI compounds, Group II-V compounds, Group III-VI compounds, Group III-V compounds, Group IV-VI compounds, Group I-III-VI compounds, Group II-IV-V compounds, Group II-IV-VI, and Group IV compounds. Examples include cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), lead sulfide (PbS), lead selenide (PbSe), lead telluride (PbTe), zinc cadmium selenide (ZnCdSe), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN), silicon and the like, mixtures of such materials, or any other semiconductor or similar materials.

In certain embodiments, the nanocrystals comprise CdSe, CdS, CdTe, PbSe, PbS, PbTe, InAs, InSb, InP, Ge, Si, Sn, Sn, HgTe, HgSe, HgS, InN, AlN, GaN, ZnTe, ZnSe, ZnS, or ZnO. In some examples, the core material is CdSe, CdS, CdTe, PbSe, PbS, PbTe, InAs, InSb, InP, Ge, Si, Sn, Sn, HgTe, HgSe, HgS, InN, AlN, GaN, ZnTe, ZnSe, ZnS, or ZnO or combinations thereof, and the shell material is CdSe, CdS, CdTe, PbSe, PbS, PbTe, InAs, InSb, InP, Ge, Si, Sn, Sn, HgTe, HgSe, HgS, InN, AlN, GaN, ZnTe, ZnSe, ZnS, or ZnO or combinations thereof. In certain embodiments, the quantum dot has a core/shell structure selected from CdSe/CdS, CdSe/ZnSe, CdSe/ZnS, CdSe/ZnTe, CdSe/CdTe, CdTe/CdSe, CdTe/CdS, CdTe/ZnSe, CdTe/ZnS, CdTe/ZnTe, CdS/ZnSe, CdS/ZnS, CdS/CdTe, CdS/CdSe, PbSe/PbS, PbS/PbSe, PbTe/PbS, PbS/PbTe, PbTe/PbSe, PbSe/PbTe, PbSe/CdSe, CdSe/PbTe, PbS/CdS, CdS/PbS, PbTe/CdTe, CdTe/PbTe, InAs/CdS, InSb/CdS, InP/CdS, InAs/CdSe, InSb/CdSe, InP/CdSe, InAs/ZnSe, InP/ZnSe, InSb/ZnSe, InAs/ZnS, InP/ZnS, InSb/ZnS, Ge/Si, Si/Ge, Sn/Si, Si/Sn, Ge/Sn, or Sn/Ge.

In some embodiments, the nanocrystals comprise one shell, but in other embodiments, the nanocrystals comprise more than one shell, such as from 2 to at least 30 shells, more typically from 2 to about 15 shells, such as 2 to 6 shells, or 2, 3, 4, 5 or 6 shells. Multiple shells can allow for additional tuning of the properties of the nanocrystal. Adjacent shells may have the same material or composition, or a different material or composition.

The size of the shell in relation to the core can also be selected to enhance or decrease certain properties of the nanocrystal. The core may be small relative to the size of the shell, and the shell may be thick relative to the core. In some embodiments, the core has a radius of from about 0.5 nm to about 3 nm, such as from about 1 nm to about 2 nm. In certain embodiments, the core has a radius of about 1.5 nm. The shell thickness is measured from the outer surface of the core to the outer surface of the nanocrystal. In some examples, the shell has a thickness of from greater than 0 nm to greater than 10 nm, such as from about 0.5 nm to about 8 nm, from about 2 nm to about 7 nm or from about 3 nm to about 6 nm. In certain examples, the shell has a thickness of about 4.2 nm and in other examples the shell has a thickness of about 5 nm.

The nanocrystals can be made by any suitable method. One exemplary method can be found in Pietryga, J. M. et al., Utilizing the Lability of Lead Selenide to Produce Heterostructured Nanocrystals with Bright, Stable Infrared Emission, J. Am. Chem. Soc. 130, 4879-4885 (2008). Large, nearly spherical PbSe nanocrystals (that is, PbSe QDs) with radii from 3.5 to 5 nm were fabricated, and then partial cation exchange was applied to create an outer CdSe shell of controlled thickness by exchanging ions of Pb²⁺ with Cd²⁺. Using a moderate reaction temperature (130° C.) the formation of homogeneous CdSe particles was avoided, and PbSe/CdSe QDs of fairly uniform sizes were produced. This procedure preserved the overall size of the QDs and allowed the gradual tuning of the aspect ratio of the resulting core/shell structure (φ, defined as the ratio of the shell thickness (H) to the total radius (R): ρ=H/R. Both the starting PbSe QDs and the final PbSe/CdSe structures exhibited a nearly spherical shape and fairly narrow size dispersity (standard deviation of the overall size is approximately 7%). The core and shell sizes within a given sample appeared less uniform, exhibiting approximately 15% dispersion.

An alternative method of forming the quantum dots comprises mixing a solution of quantum dot cores in a suitable solvent, such as octadecene (ODE) and oleylamine. A suitable solvent is any solvent that will dissolve the quantum dot cores. Exemplary solvents include, but are not limited to, hexane, toluene, chlorinated solvents such as chloroform and dichloromethane, THF, alcohols such as methanol, ethanol propanol and isopropanol, cyclohexane or combinations thereof. The mixture is then degassed. The degassing may take place at room temperature or at elevated temperatures. In some embodiments, the degassing is started at room temperature and continues for an effective period of time, such as for 30 minutes to greater than 2 hours, or for 1 hour to 1.5 hours, and then the temperature is raised for a second period of time, such as from 50° C. to 150° C. or from 75° C. to 120° C. The degassing may continue at the elevated temperature for a sufficient period of time to remove the solvent and any water, such as for from 1 minute to greater than 30 minutes, or from 5 minutes to 15 minutes. In certain embodiments, the degassing continues at 100° C. for 5 minutes.

The solution is then stirred in an inert atmosphere, such as under nitrogen or argon, and the temperature is raised to above 300° C., such as from greater than 300° C. to 350° C., or from 305° C. to 315° C. In certain embodiments, the temperature is raised to above 310° C. At 200° C. a solution of Cd-oleate in ODE and a separate solution of octanethiol dissolved in ODE are added slowly, such as at a rate of 2.5 mL per hour. After 2 hours a portion of oleic acid is added and after 4 hours a second portion of oleic acid is added. After 8 hours, the solution is stirred for an additional 15 minutes at about 310° C., and then heating is discontinued. The final product is recovered by precipitation, such as by the addition of acetone. By varying the amounts of the cd-oleate and octanethiol and the addition times, quantum dots of different desired shell-thicknesses can be produced.

B. Polymer

In some embodiments, the polymer matrix comprises a polymer that is at least partially, and may be substantially, transparent to light, such as visible light, IR light, UV light or combinations thereof. The polymer matrix may comprise a polymer suitable for processing into any desired form, such as: a planar substrate or self-standing bulk material; a coating film, such as for a coating on glass or plastic substrates; an intercalated layer, such as between two glass or plastic substrates, typically planar substrates; a fiber, such as an optical fiber made of polymeric materials (plastic optical fiber); or a viscous fluid suitable for making transparent packaging. In some embodiments, the polymer matrix is a polymer matrix suitable for use in a semi-transparent or substantially transparent window.

In some examples, the polymer matrix comprises a polymer selected from poly acrylate and poly acryl methacrylate, polyolefin, poly vinyl, epoxy resin (polyepoxide), polycarbonate, polyacetate, polyamide, polyurethane, polyketone, polyester, polycyanoacrylate, silicone, polyglycol, polyimide, fluorinated polymer, polycellulose, or poly oxazine. Exemplary polymers include, but are not limited to, polyethylene, polypropylene, polymethylpentene, polybutebe-1, polyisobutylene, ethylene propylene rubber, ethylene propylene diene monomer rubber, polyvinyl chloride, polybutadiene, polystyrene, polyvinyl acetate, polyvinyl alcohol, polyacrylonitrile, bisphenol-A, bisphenol-F, polytetrafluoroethylene, polyvinylfluoride, polyvinylidene fluoride, polychlorotrifluoroethylene, ethylene-carbon monoxide co-polymer, polyglycolide, polylactic acid, polycaprolactone, polyhydroxyalkanoate, polyhydroxybutyrate, polyethylene adipate, polybutylene succinate, polyethylene glycol, methyl cellulose, hydroxyl methyl cellulose, polymethyl methacrylate, polymethyl acrylate, polyethyl acrylate or combinations thereof.

In some embodiments, the polymer matrix comprises an acrylate polymer, and may be an alkyl acrylate polymer. The acrylate polymer may also be a substituted acrylate polymer, where one or more of the vinyl hydrogens in the monomer is replaced by one or more substituent groups. In some embodiments, the substituent group is an alkyl group, such as methyl, ethyl, propyl, isopropyl, or butyl. Exemplary acrylate monomers that can be used to form the polymers include, but are not limited to, methyl acrylate, ethyl acrylate, propyl acrylate, butyl acrylate, 2-chloroethyl acrylate, methyl methacrylate (MMA), ethyl methacrylate, butyl methacrylate, 2-ethylhexyl acrylate, hydroxyethyl methacrylate, or trimethylolpropane triacrylate (TMPTA). In particular embodiments, the polymer matrix is polymethyl methacrylate (PMMA).

The nanocrystals may be dispersed in the polymer matrix. In some embodiments, the quantum dots are dispersed in the polymer matrix by a process that inhibits or substantially prevents aggregation of the nanocrystals. The dispersion may be such that an emission efficiency of the nanocrystals in the polymer matrix is substantially the same as the emission efficiency of the nanocrystals in a solution, such as a hexane solution. In some embodiments, the emission efficiency of the nanocrystals in the polymer matrix is at least 90% of the emission efficiency of the nanocrystals in a hexane solution, such as at least 95%, at least 98% or at least 99%.

In some embodiments, the nanocrystals are dispersed such that the average distance between the nanocrystals is greater than an energy transfer distance. Energy transfer between nanocrystals typically occurs at distances up to about 15-20 nm. Therefore, in certain embodiments, the average distance between the nanocrystals is greater than 15 nm, such as greater than 20 nm, greater than 25 nm or greater than 30 nm. In some embodiments, the concentration of nanocrystals in the polymer matrix is from greater than 0 to 10% relative to the weight of the polymer matrix, such as from greater than 0 to 5%, from greater than zero to 1% or from greater than zero to 0.5%. In certain embodiments, the concentration of nanocrystals in the polymer matrix is from 0.01% to 0.1%, and may be 0.05%.

In other embodiments, concentration of nanocrystals in the polymer matrix is from 0 to 10 grams per kilogram of polymer matrix, such as from 1 gram to 5 grams. In certain embodiments, the concentration of nanocrystals in the polymer matrix is 2 grams per kilogram of the polymer matrix.

C. Sol-Gel

In some embodiments, the nanocrystals are mixed with a lower alcohol, a non-polar solvent and a sol-gel precursor material, and the resultant solution can be used to form a solid composition. For example, the solution can be deposited onto a suitable substrate to yield substantially homogeneous, solid compositions from the solution of nanocrystals and sol-gel precursor. “Homogeneous” means that the nanocrystals are substantially uniformly dispersed in the resultant product. In some instances, non-uniform dispersal of the nanocrystals is acceptable. In some embodiments of the invention, the solid compositions can be transparent or optically clear.

The lower alcohol used in this process is generally an alcohol containing from one to four carbon atoms, i.e., a C₁ to C₄ alcohol. Among the suitable alcohols are included methanol, ethanol, n-propanol, isopropanol, n-butanol, sec-butanol and t-butanol.

The non-polar solvent is used in the process to solubilize the nanocrystals and should be miscible with the lower alcohol. The non-polar solvent is generally chosen from among tetrahydrofuran, toluene, xylene and the like. Tetrahydrofuran is a preferred non-polar solvent in this process.

Sol-gel processes generally refer to the preparation of a ceramic material by preparation of a sol, gelation of the sol and removal of the solvent. Sol-gel processes are advantageous because they are relatively low-cost procedures and are capable of coating long lengths or irregularly shaped substrates. In forming the sol-gel based solution used in the processes of the present invention, suitable sol-gel precursor materials are mixed with the other components.

Additional information regarding sol-gel processes can be found in Brinker et al., “Sol-Gel Science, The Physics and Chemistry of Sol-Gel Processing”, Academic Press, 1990, which is incorporated herein by reference. Among suitable sol-gel precursor materials are included metal alkoxide compounds, metal halide compounds, metal hydroxide compounds, combinations thereof and the like where the metal is a cation from the group of silicon, titanium, zirconium, and aluminum. Other metal cations such as vanadium, iron, chromium, tin, tantalum and cerium may be used as well. Sol solutions can be spin-cast, dip-coated, printed or sprayed onto substrates in air. Sol solutions can also be cast into desired shapes by filling molds or cavities as well. Suitable metal alkoxide compounds include, but are not limited to, titanium tetrabutoxide (titanium (IV) butoxide), titanium tetraethoxide, titanium tetraisopropoxide, zirconium tetraisopropoxide, tetraethoxysilane (TEOS). Suitable halide compounds include, but are not limited to, titanium tetrachloride, silicon tetrachloride, aluminum trichloride and the like.

The sol-gel based solutions generated in this process are highly processable. They can be used to form solid compositions in the shape of planar films and can be used to mold solid compositions of various other shapes and configurations. Volume fractions or loadings of the nanocrystals can been prepared as high as about 13 percent by volume and may be as high as up to about 30 percent by volume. Further, certain embodiments of the present invention have allowed preparation of solid compositions having a refractive index of 1.9, such refractive index values being tunable.

In alternative embodiments, the process for incorporating nanocrystals into a sol-gel host matrix further comprises admixing the nanocrystals with a polymer. Typically this is done in a suitable solvent, such as a solvent that will dissolve the polymer. A person of ordinary skill in the art will understand that the nature of the solvent will depend on the polymer that needs to be dissolved. Suitable solvents include, but are not limited to, chlorinated solvents such as chloroform, dichloromethane, dichloroethane and tetrachloroethane. The polymer solution is then added to a solution of nanocrystals in a suitable solvent, such as halogenated solvent, such as chloroform. In some embodiments, the nanocrystals have been previously separated from their growth media, such as by precipitation. When sufficient polymer has been added such that the nanocrystals are soluble in an alcohol, such as ethanol, the solvent is evaporated. The nanocrystal/polymer mixture is dissolved in alcohol, typically in an inert atmosphere. In some instances where minor amounts of nanocrystal-polymer adduct or complex remained un-dissolved in the alcohol, a co-solvent, such as tetrahydrofuran and the like, is used with the alcohol to completely or nearly completely solubilize the adduct or complex. The solution is then mixed with a sol-gel precursor solution, e.g., a titania sol precursor material, and formed into a solid composite, such as a film on a substrate. Once incorporated into the sol-gel matrix, the nanocrystals are highly stable and are not then soluble within hydrocarbon solvents such as hexane. The alcohols, used with the alcohol soluble colloidal nanocrystal-polymer adduct or complexes in the present invention, generally include ethanol, 1-propanol and 1-butanol. Other alcohols may be used as well, but alcohols having lower boiling points are preferred for improved processability with sol-gel precursors.

Additional information regarding the process of preparing a composition comprising quantum dots dispersed within a sol-gel host matrix can be found in U.S. Pat. Nos. 7,226,953, 7,723,394 and 8,198,336, which are incorporated herein by reference.

### IV. Methods of Making the Composition

Also disclosed herein are embodiments of a method for making the composition. In some embodiments, the method comprises separating the polymerization process into two steps: a pre-polymerization step at a first temperature; followed by a second polymerization step at second temperature. The pre-polymerization step is carried out at a temperature suitable to initiate polymerization. A person of ordinary skill in the art will understand that different monomers and/or different polymerization initiators may require different temperatures to initiate polymerization. In some embodiments, the temperature for the pre-polymerization is from less than 25° C. to greater than 150° C., such as from 50° C. to 120° C., from 70° C. to 100° C. or from 80° C. to 85° C. In certain embodiments, the pre-polymerization is performed in the presence of a first polymerization initiator. The initiator can be any initiator suitable for the particular monomer being used. Suitable initiators include, but are not limited to: peroxides, such as lauroyl peroxide, di-tert-butyl peroxide, benzoyl peroxide, methyl ethyl ketone peroxide, tert-butyl peracetate, tert-butyl hydroperoxide and acetone peroxide, azo compounds such as azobisisobutyronitrile (AIBN), 1,1′-azobis(cyclohexanecarbonitrile) (ABCN) and 4,4′-azobis(4-cyanovaleric acid) (ABVA); persulfates, such as potassium persulfate, sodium persulfate and ammonium persulfate; organometallics, such as triethylaluminum and titanium tetrachloride; or combinations thereof. Sufficient initiator is added to the monomer to initiate the polymerization reaction. In some embodiments, the amount of initiator added to the monomer is from greater than 0 to greater than 200 ppm wt/wt with respect to the monomer, such as from 50 to 200 ppm or from 75 to 150 ppm. In certain embodiments, 100 ppm wt/wt with respect to the monomer of the initiator is added.

The pre-polymerization reaction is then quenched, such as by cooling to a temperature sufficient to slow down or substantially stop the polymerization reaction. This temperature may be a temperature below an activation temperature of the initiator. In some embodiments, the reaction is quenched by cooling to a temperature equal to or less than 70° C., such as from greater than 0° C. to 60° C. or below, from 0° C. to 55° C. or below, or from 25° C. to 50° C. or below. In some examples, the quenching leads to the formation of a viscous solution comprising reactive radical polymer chains in liquid monomer. In some embodiments, the polymerization is quenched when the conversion yield from monomer to polymer is less than 30%, such as less than 20% or less than 10%.

A dispersion of nanocrystals monomer is prepared separately. The nanocrystals are synthesized by standard methods known to a person of ordinary skill in the art. In some embodiments, the nanocrystals are colloidal nanocrystals and are synthesized in solution. The solvent may be an organic solvent, such as hexane. The nanocrystals are initially mixed with a second polymerization initiator. The second polymerization initiator may be the same as the first polymerization initiator, or it may be a different initiator. In some embodiments, the second polymerization initiator has a lower activation temperature than the first polymerization initiator. The nanocrystals may also be pre-mixed with a second amount of the monomer. The nanocrystals are mixed with a sufficient amount of the second initiator such that, when the mixture is mixed with the quenched pre-polymerization reaction, the initiator will initiate polymerization of the unreacted monomer. In some embodiments, the amount of the second initiator is from greater than 0 to greater than 500 pm wt/wt with respect to the second amount of the monomer, such as from 200 ppm to 500 ppm or from 350 ppm to 450 ppm. In certain embodiments, the amount of the second initiator is 400 pm wt/wt with respect to second amount of the monomer. In other embodiments, the amount of the amount of the second initiator is from greater than 0 to greater than 20% wt/wt with respect to the quenched pre-polymerization reaction mixture, such as from 5% to 20% or from 7.5% to 15%. In certain embodiments, the amount of the second initiator is 10% wt/wt with respect to the quenched pre-polymerization reaction mixture.

Mixing the nanocrystals with the initiator, and optionally monomer, may be performed in solution, or may be performed without a solvent. In certain embodiments, the nanocrystals are synthesized in a solvent, which is then evaporated prior to the initiator being added. Typically, the nanocrystals and initiator are maintained under an inert atmosphere, such as an argon or nitrogen atmosphere. In some examples, mixing is performed in an inert atmosphere. Mixing is continued until the nanocrystals are dispersed in the initiator and monomer. Dispersing the quantum dots in the monomer can be achieved by any suitable method, such as by sonication, stirring, shaking and/or other agitation of the mixture. In some embodiments, the dispersing of the nanocrystals continues until a substantially homogeneously dispersion of nanocrystals in the mixture is achieved.

The dispersion of nanocrystals in the monomer and second initiator is mixed with quenched pre-polymerization reaction. The mixture is then cast into a mold and heated at a temperature sufficient for the second polymerization reaction to proceed, and for a time sufficient for the second polymerization reaction to proceed to form a desired polymer matrix. In some embodiments, the mixture is heated at a temperature of from less than 25° C. to greater than 150° C., such as from 30° C. to 120° C., from 50° C. to 100° C., from 50° C. to 80° C. or from 50° C. to 60° C. In some embodiments, the temperature at which the second polymerization proceeds is less than the temperature used for the pre-polymerization reaction. In certain embodiments, the pre-polymerization reaction is heated to 80° C. and the second polymerization reaction is heated to 55° C. The mixture may be heated for from less than one hour to greater than 96 hours, such as from 12 hours to 72 hours, or from 24 hours to 60 hours. In some examples, the mixture is heated at 55° C. for 48 hours. In some embodiments, the pre-polymerization reaction is a fast polymerization and the second polymerization reaction is a slow polymerization, such that a rate constant of propagation of the pre-polymerization reaction is greater than a rate constant for the second polymerization reaction. In some embodiments, after the second polymerization reaction has finished, the amount of residual monomer is less than 1%, which is in compliance with international safety requirements.

After the second polymerization reaction is complete, the polymer matrix may be additionally post-cured. Post-curing can occur at any suitable temperature, such as from greater than ambient temperature to greater than 200° C., from 50° C. to 150° C. or from 100° C. to 125° C. The composition is post-cured for a time suitable to achieve a desired result, such as a desired hardness. The time may be from less than 1 hour to greater than 48 hours, such as from 6 hours to 24 hours or from 12 hours to 18 hours. In certain embodiments, the post-curing is performed at 115° C. overnight.

The above approach has advantages for applications of nanocrystals luminescent solar concentrators (NC-LSCs). First, it requires a very limited amount of radical initiator (a few hundreds of ppm, w/w), which is mostly responsible for photoluminescence quenching. Further, the pre-polymerization step reduces the formation of heterogeneities in the polymer matrix, thus increasing the optical transparency of the final composition. Additionally, the high viscosity of the composition, after the pre-polymerization reaction has been quenched, reduces the mobility of all chemical species, thereby preventing nanocrystal aggregation and limiting the interaction between the nanocrystals and the radical initiators. Also, in some embodiments, no cross-linking agent is used during the polymerization process.

### V. Applications

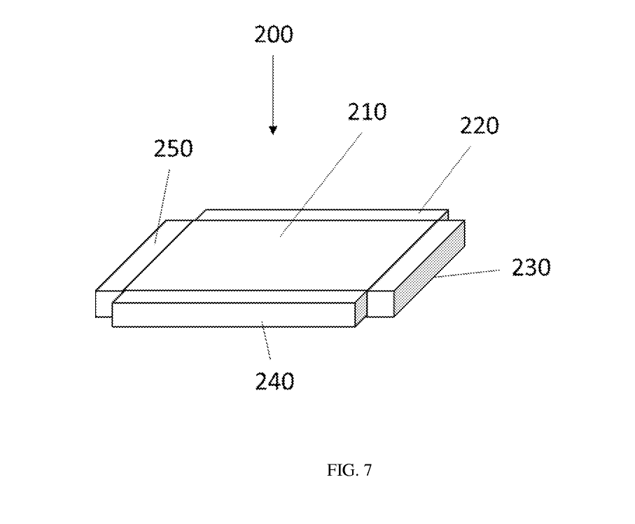

The disclosed compositions can be used in a variety of applications and devices such as solar cells and other applications comprising photovoltaic cells. One exemplary embodiment of a device is schematically shown in FIG. 7. With reference to FIG. 7, device 200 comprises a waveguide 210 comprising a composition as disclosed herein, comprising a polymer matrix and nanocrystals. The waveguide 210 comprises photovoltaic cells, with the exemplary illustrated embodiment comprising four photovoltaic cells 220, 230, 240 and 250. The composition receives incident light, such as from the sun, and some of that light is absorbed by the nanocrystals. The photovoltaic cells receive the luminescence emissions from the nanocrystals.

In alternative embodiments, one, two or three of the photovoltaic cells, 220, 230, 240 and 250 may be replaced with reflectors and/or diffusers, such as white or silvered reflectors, reflectors coated with aluminum or other metals, or multilayer stacks of dielectric layers to form distributed Bragg reflectors. The function of the reflector is to reflect light back into the composition and towards the photovoltaic cell(s). In some embodiments, the reflectors are diffuse reflectors.

In other examples, the waveguide 210 may not be surrounded by photovoltaic cells and/or reflectors. In these examples, any edge that does not have a reflector or photovoltaic cell may allow light to escape, thereby reducing the overall efficiency of the device.

In some embodiments, the waveguide 210 is transparent or semi-transparent, allowing the device to be used as a window. In such embodiments, the photovoltaic cells and reflectors and/or diffusers, if present, may be placed in the window frame. The window maybe of any suitable shape, such as a square or rectangle, circle, ellipse, triangle, pentagon, hexagon, octagon, arch, cross, star or an irregular shape. The window may be colored or colorless, tinted or not tinted, and in all possible combinations. In some embodiments, the window is two way, that is visible light can pass in both directions through the window pane. In other embodiments, the window is a ‘one-way’ window, thereby restricting the passage of visible light through the window. Ultraviolet and infrared light may still be able to penetrate the window. In other embodiments, the window can be transparent in the visible and IR but strongly absorb UV light. In some embodiments, the window is in a building or in a transportation device, such as an automobile, ship or airplane.

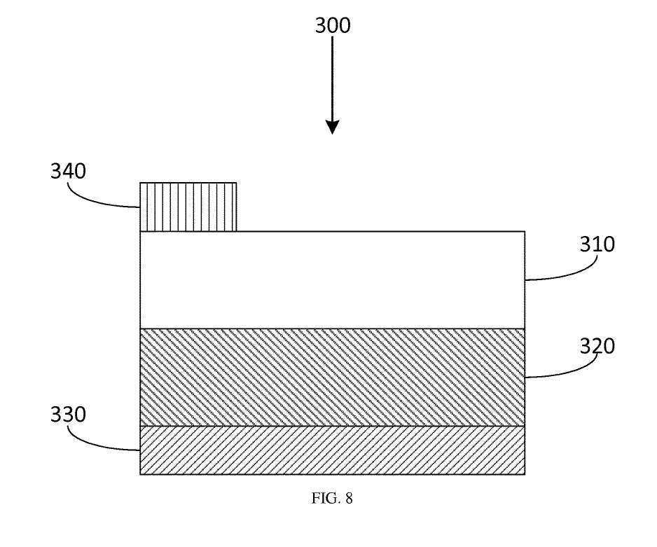

FIG. 8 provides a cross-sectional schematic of an exemplary photovoltaic cell 300. A single-crystal photovoltaic cell comprises at least two semiconductor layers, an n-type layer 310, and a p-type layer 320. The “p” and “n” types of semiconductors correspond to “positive” and “negative” because of their abundance of holes or electrons (the extra electrons make an “n” type because of the negative charge of the electrons). Although both materials are electrically neutral, n-type semiconductors typically have excess electrons and p-type semiconductors have excess holes. Positioning these two materials adjacent to each other creates a p/n junction at their interface, thereby creating an electric field. Materials suitable for the n-type layer include, but are not limited to, CdS, ZnS, ZnSe, Zn(O,S), (Zn,Mg)O, In₂S₃, In₂Se₃ and silicon, which may or may not be doped, such as with phosphorous or arsenic. Exemplary materials suitable for the p-layer include, but are not limited to, silicon, which may or may not be doped, such as with boron, CdS, CdTe, ZnTe, GaIAs, GaAs, GaInP and the like. In some embodiments, the n-type material has a band gap E_{g} from greater than the band gap of the p-type layer. Each layer may comprise multiple sub-layers. When cell 300 is exposed to light, some photons are reflected, some pass through the cell, and some are absorbed. When sufficient photons are absorbed by the absorber layer, electrons are freed from the semiconductor material and migrate to a contact. This creates a voltage differential, similar to a household battery. When the two layers are connected to an external load, through contacts 330 and 340, the electrons flow through the circuit producing electricity.

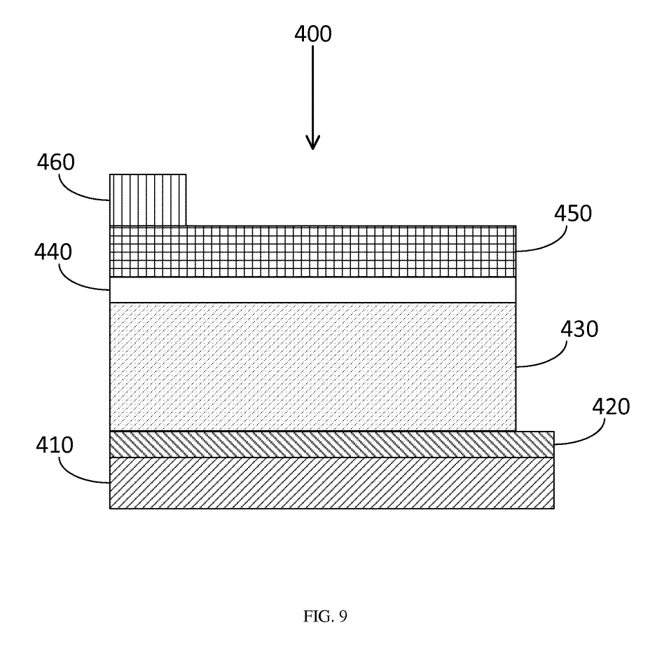

FIG. 9 provides a schematic diagram of a photovoltaic device in a substrate configuration. With reference to FIG. 9, at the base of device 400 is substrate 410. Substrate 410 can be made from any suitable material, such as glass, ceramic, plastic or bioplastic, polymers, including high temperature polymers, metals, metal foils, such as copper, aluminum or stainless steel, and metal alloys and combinations thereof. The substrate can be flexible or rigid and can be transparent or opaque. The substrate material will be sufficiently heat resistant to withstand fabrication processes, such as an annealing process. On top of the substrate is a bottom contact layer 420. Bottom contact layer 420 can be made using any suitable material that can conduct electricity, such as a metal, alloy, heavily doped p-type material, or a degenerate semiconductor. In some embodiments bottom contact layer 420 comprises a metal. On top of bottom contact layer 420 is p-layer 430, comprising a material suitable for a p-type layer, including, but not limited to, silicon, which may or may not be doped, such as with boron, CdS, CdTe, ZnTe, GalAs, GaAs, GaInP, or Cu₂O which may or may not be doped, such as with nitrogen, silicon, germanium or a transition metal. Buffer layer 440 and the window 450 together form an n-type layer. Buffer layer 440 can be formed from any material suitable for an n-type layer. Preferably, buffer layer 440 comprises an n-type material with a band gap E_{g} from greater than the band gap of the p-type layer, to less than the band gap of the window layer, preferably from about 1.5 to about 3.5 eV, more preferably about 2.5 eV. Exemplary materials for the buffer layer 440 include, but are not limited to, CdS, ZnS, ZnSe, Zn(O,S), (Zn,Mg)O, In₂S₃, In₂Se₃ and silicon, which may or may not be doped, such as with phosphorous or arsenic. The window layer 450 is formed from any material suitable for an n-type layer that allows photons of light to pass to the layers below. Preferably window layer 450 comprises an n-type material with a band gap E_{g} of greater than about 3 eV. Exemplary suitable materials for the window layer include, but are not limited to, ITO (indium tin oxide), SnO₂, FTO (fluorine doped tin oxide), ZnO, ZnO:Al (Al doped ZnO) and ZnO:B (boron doped ZnO). Top contact electrode 460 is placed above window layer 450. Top contact electrode 460 can be formed from any suitable material that can conduct electricity, such as a metal, alloy, heavily doped p-type material or a degenerate semiconductor.

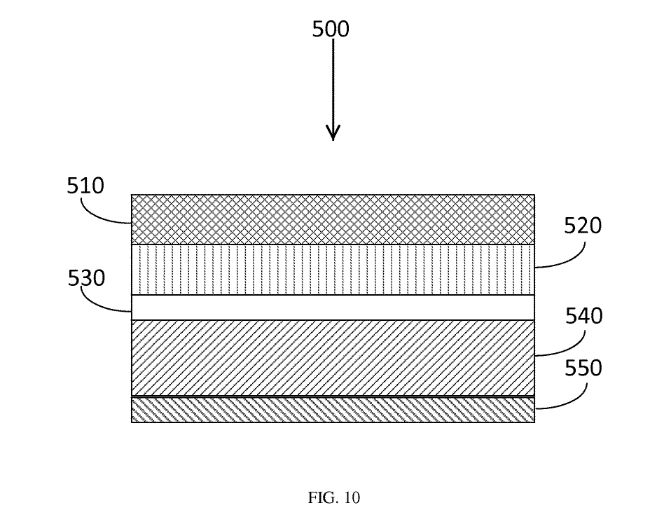

FIG. 10 provides a cross-sectional schematic of a superstrate configuration for an exemplar photovoltaic device 500. Device 500 has a substrate 510. Substrate 510 typically is transparent, such as, for example, a glass substrate. In certain embodiments, substrate 510 is a composition comprising a polymer matrix and quantum dots, as disclosed herein. Light shines through transparent substrate 510 and through the n-type layer comprising a window layer 520 and a buffer layer 530. Window layer 520 and buffer layer 530 can comprise any suitable materials, such as those listed above with respect to device 400. Below buffer layer 530 is the p-type absorber layer 540. Layer 540 comprises any materials suitable for a p-layer such as those disclosed for device 400 above. Below the p-layer 540 is the bottom contact 550. Contact 550 can be formed from any suitable material that can conduct electricity, such as a metal, alloy, heavily doped p-type material or a degenerate semiconductor.

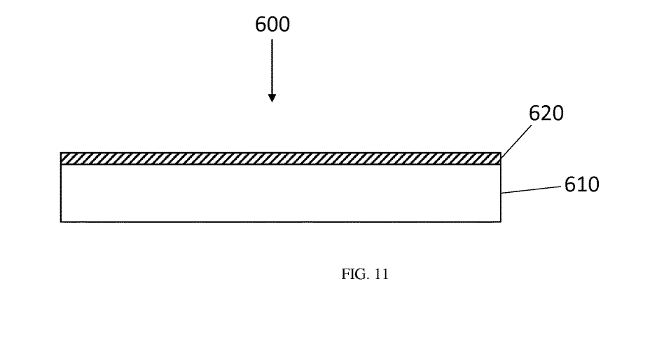

In other embodiments, the composition is processed to form a film, which is coated onto a substrate, such as a glass or transparent substrate (FIG. 11). With reference to FIG. 11, device 600 comprises a substrate 610, such as a glass slab or sheet or a polymer slab or sheet, for example, a window pane, with a coating of a film 620 comprising a disclosed composition. In FIG. 11, the coating is shown completely covering one face of the substrate, but a person of ordinary skill in the art will appreciate that instead, the film may only partially cover the face of the slab. Additionally, in the exemplary embodiment shown in FIG. 11, the film is shown on only one face of the substrate, but in alternative embodiments both faces of the substrate are covered. The substrate 610 may be a glass substrate, or polymer substrate such as a polyacrylate slab or polycarbonate slab. In some embodiments, the substrate 610 is a window pane, such as a window pane for a building or a mode of transport, such as an automobile. One advantageous feature of forming the composition into a film is that the film can be applied to existing glass or polymer substrates, such as to existing windows, rather than having to replace the window pane.

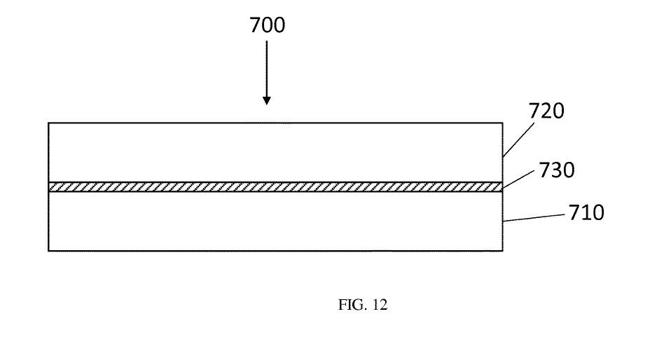

In alternative embodiments, the composition may be positioned between two substrate slabs, such as between two glass or transparent plastic sheets (FIG. 12). With reference to FIG. 12, device 700 includes two substrate slabs or sheets 710 and 720. These may be made from any suitable material. Suitable materials include materials transparent or semi-transparent to visible light, infrared light ultraviolet light or a combination thereof or materials not transparent to light. In some embodiments, both slabs 710 and 720 are transparent to the light, but in other embodiments, only one is transparent to the light. In some embodiments, one may have more transparency than the other, such as a tinted and non-tinted pair of slabs. Composition 730 is intercalated between the slabs. In some embodiments, composition 730 is formed into a film which at least partially coats one or both of the slabs. Alternatively, composition 730 may be formed into a slab, which is placed between the two substrate slabs 710 and 720, or composition 730 may be a viscous fluid held between the slabs.

### VI. Examples

A. Methods

Materials

Methyl methacrylate (MMA, 99%, Aldrich), purified with basic activated alumina (Sigma-Aldrich), was used as a monomer for the preparation of the polymeric nanocomposites. 2,2′-Azobis(2-methylpropionitrile) (AIBN, 98%, Aldrich) and lauroyl peroxide (98%, Aldrich) were used as initiators without purification.

Fabrication of Nanocrystal Quantum Dots

I. Chemicals.

Oleic acid (OA, technical grade 90%), lead(II) oxide (99.999%), cadmium oxide (99.998%), and selenium shot (99.999%) were purchased from Alfa Aesar; 1-octadecene (ODE, technical grade 90%), bis(trimethylsilyl)sulfide (95%), cadmium cyclohexanebutyrate (24% Cd), Bis(trimethylsilyl)sulfide (TMS₂S, 95%), oleylamine (80-90%) and sulfur (99.5%) were purchased from Acros Organics; tributylphosphine (97%) was purchased from Sigma Aldrich; trioctylphosphine (TOP, 97%) was purchased from Strem.

II. Synthesis of R=4.8 nm PbSe QDs.

Pb-oleate precursor was prepared by heating a solution containing 0.892 g of PbO, 4 mL of oleic acid (OA), 16 mL of 1-octadecene (ODE) to 120° C. under vacuum for half an hour. Then the solution was purge with argon and heated to 180° C. A syringe containing 50 μL of diisobutylphosphine and 1 mL of 2 M trioctylphosphine selenide (TOPSe) was rapidly injected. The solution was then cooled to 160° C. for 8 minutes. Purification process was operated inside the glove box to prevent QDs oxidation. Excess ethanol was added to the solution to precipitate QDs and the precipitate was re-dissolved in toluene.

Pristine R=3.5 nm, 4.0 nm, 4.1 nm, 6.6 nm PbSe QDs were prepared in the similar way except a reaction time at 160° C. of 2 minutes, 4 minutes, 5 minutes, and 30 minutes respectively.

III. CdSe Shell Growth.

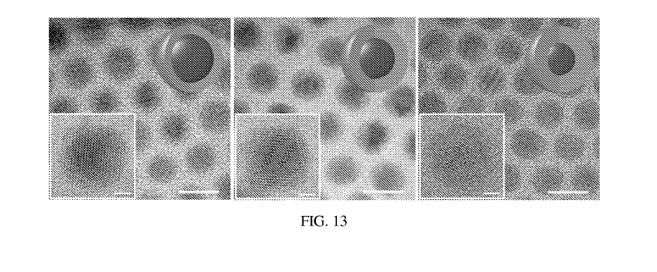

A three neck flask containing 1.28 g of CdO, 10 mL of OA, and 10 mL of ODE was heated up to 260° C. for 30 minutes to form a clear solution. Then the solution was vacuumed at 120° C. for 1 hour to remove water. In the cation exchange, PbSe QDs dispersion solution was added to the as-prepared Cd-oleate solution at room temperature. Then the solution was vacuumed to remove toluene. Cation exchange was operated at 130° C. for 18 hours to prepare a 2.5 nm-thick shell. Reaction progress was monitored by determining shell thickness of small aliquots taken periodically. FIG. 13 provides transmission electron microscopy (TEM) images of core/shell PbSe/CdSe QDs with the same overall radius (R=4 nm) and different shell thicknesses (H=1.08 nm, 1.6 nm, and 2.08 nm; from left to right). Scale bar is 10 nm.

Fabrication of the Nanocrystal-Polymer Composition

Polymethylmethacrylate (PMMA) nanocomposite disks were prepared by bulk polymerization of MMA with lauroyl peroxide (400 ppm w/w with respect to MMA) at 80° C. for 24 hours under an argon atmosphere. First, the quantum dot (QD) solvent, hexane, was evaporated in a continuous argon flow, then lauroyl peroxide was added and the two powders were kept for two hours under argon flow.

In the meantime, three freeze-pump-thaw cycles were performed on the purified monomer in order to remove the oxygen. At this point the monomer was added to the flask containing the QDs and the initiator under argon atmosphere. The mixture was homogenously dispersed by ultrasound treatment and then inserted in an oven. The PMMA plate was fabricated by bulk polymerization using the industrial cell-casting process. The process was characterized by two steps. First, the so-called “syrup” was prepared: the monomer, purified through a basic aluminum oxide column, was heated in a beaker to 80° C. When the MMA temperature stabilized, AIBN (100 ppm w/w with respect to MMA) was added. At that point, the prepolymerization (an exothermic process) took place and the monomer temperature increased up to the MMA boiling temperature (95° C.); when the monomer achieved the stage of vigorous boiling the syrup was quenched. In the second step, the prepolymer was degassed by four freeze-pump-thaw cycles in order to remove oxygen and introduce argon atmosphere and then mixed with the dispersion of the QDs in MMA containing lauryl peroxide (400 ppm w/w with respect to MMA) described above (10% w/w with respect to the syrup). Finally, the viscous liquid was introduced into the casting mold under argon flow where the polymerization reaction proceeded. A casting mold was made by two glass plates sealed with a polyvinyl chloride (PVC) gasket (in order to preserve the inert atmosphere) and clamped together. The clamps contained springs in order to accommodate the shrinkage of the polymer plate during the polymerization process. The casting mold was placed in a water bath at 55° C. for 48 hours. Finally the bar was post-cured in the oven at 115° C. overnight.

Characterization of the Polymeric Nanocomposite

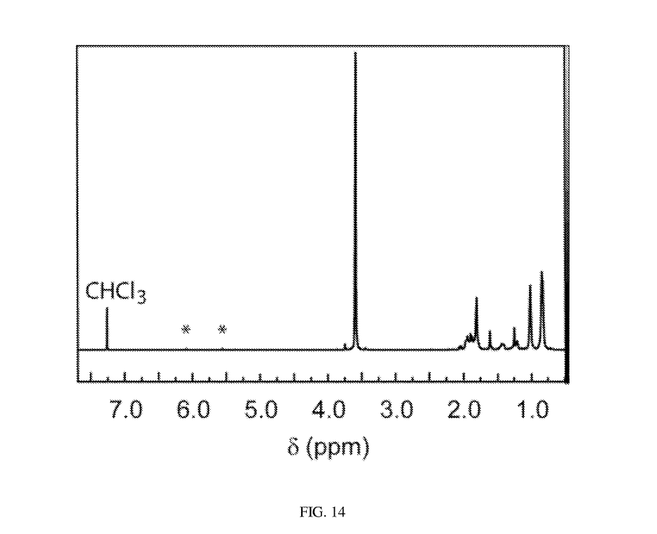

The amount of residual monomer in the PMMA composites was extracted from the ¹H Nuclear Magnetic Resonance (NMR) spectra, recorded on samples dissolved in deuterated chloroform by using an Avance 500 NMR spectrometer (Bruker). Tetramethylsilane was used as the internal standard. FIG. 14 shows the ¹H NMR spectrum of the PMMA matrix and illustrates the relative amount of the unreacted monomer compared to the bulk polymer.

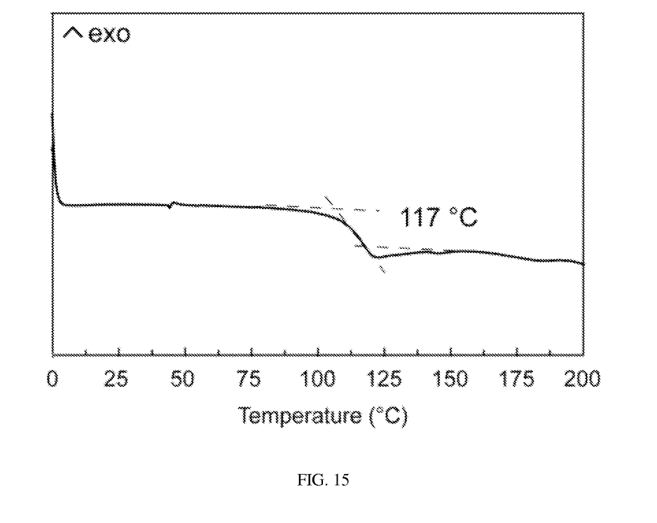

The glass transition temperature of the PMMA matrix was measured by Differential Scanning calorimetry (DSC) using a Mettler Toledo Stare thermal analysis system. The thermal program was characterized by a double cycle: the heating from 0° C. to 200° C. at 10° C. per minute, and the cooling from 200° C. to 0° C. at −10° C. per minute. FIG. 15 provides a differential scanning calorimetry curve of the PMMA plate showing a glass transition temperature about 117° C., comparable to industrial grade PMMA.

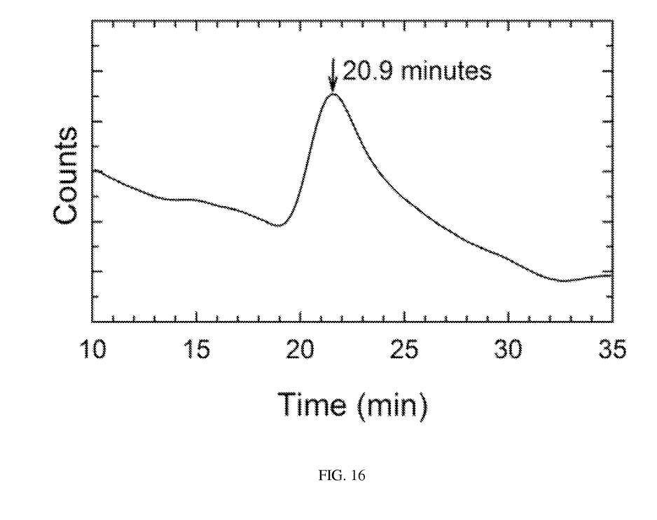

Molecular weights and molecular weight distributions of PMMA matrices were determined by Gel Permeation Chromatography (GPC) using a WATERS 1515 isocratic equipped with a HPLC Pump, WATERS 2414 refractive index detector, four Styragel columns (HR2, HR3, HR4 and HR5 in the effective molecular weight range of 500-20 000, 500-30 000, 50 000-600 000 and 50 000-4 000 000 respectively) with tetrahydrofuran (THF) as the eluent at a flow rate of 1.0 ml per minute. The GPC system was calibrated with standard polystyrene from Sigma-Aldrich. GPC samples were prepared by dissolution in THF. The solution was stirred at 80° C. under reflux for 24 hours. The QDs were precipitated in THF and removed by centrifugation (6000 RPM for 15 minutes). The supernatant made of the polymeric matrix dissolved in the eluent was filtered with a hydrophobic PTFE membranes (pore size 0.2 μm) and measured. FIG. 16 provides the gel permeation chromatography (GPC) measurements of the PMMA matrix. The retention time of 20.974 minutes corresponded to an average molecular weight Mw of approximately 1 100 000 g mol⁻¹ (Polydispersity Index, PDI=1.75).

Spectroscopic Studies

All spectroscopic studies were carried out using hexane solutions of QDs loaded into quartz cuvettes and QD-PMMA nanocomposites. In the measurements of PL dynamics, the samples were vigorously stirred to avoid the effects of photocharging. Absorption spectra of QD solutions were measured with a Cary 50 UV-Vis spectrophotometer. Photoluminescence (PL) spectra and transient PL measurements were carried out using excitation with <70 ps pulses at 3.1 eV from a pulsed diode laser (Edinburgh Inst. EPL series). The emitted light was collected with charged-coupled device (CCD) coupled to a spectrometer or a photomultiplier tube coupled to time-correlated single-photon counting electronics (time resolution approximately 150 ps). Optical measurements on LSCs were carried out using a 473 nm continuous-wave laser as an excitation source and detecting emission with a CCD coupled to a spectrometer. The same setup in combination with an integrating sphere was used for PL quantum yield measurements.

Monte-Carlo Ray Tracing Simulations of the Luminescent Solar Concentrator

The theoretical analysis of the efficiency of the LSC was performed via a Monte Carlo ray tracing technique. All LSC dimensions by far exceeded wavelengths of photons within the energy range of interest (500-700 nm). Therefore, propagation of a photon within the LSC was modeled as a propagation of a ray (beam) subject to refraction and reflection at the air-LSC interfaces according to Fresnel laws. The stochastic nature of the simulation was reflected in the fact that the ray was not split upon reaching an interface but rather either transmitted or reflected with the probabilities proportional to respective energy fluxes given by Fresnel laws. The dependence of these probabilities on the state of polarization of the incident ray (e.g., s-or p-polarized) was also taken into account. A specific event (i.e., transmission or reflection) was chosen according to random drawing.

Inside the LSC material, for each photon, the inverse transform sampling method was applied to randomly generate the length of the optical path before this photon was absorbed by a QD. Path lengths followed the exponential attenuation law determined by the wavelength-dependent absorption coefficient, α(λ), related to the absorption cross-section, σ(λ), and the QD concentration, N_{QD}, by α(λ)=N_{QD}σ(λ). Since the mean path length, given by the inverse absorption coefficient was always much greater than the average distance between the QDs, there was no need to keep track of an explicit position of each QD; therefore, the LSC QD-PMMA material was considered within the effective medium approach, that is, as a uniform material with the absorption coefficient defined above.

Once a photon was absorbed by the QD, the subsequent fate of the excitation (i.e., re-emission or non-radiative relaxation) was again determined by the Monte Carlo sampling according to the PL quantum yield. The direction of re-emitted photons was distributed uniformly across the 4π sphere and the re-emission wavelength was determined using the rejection sampling applied to the PL spectrum obtained from experiment.

The ultimate fate of each photon was either non-radiative relaxation or escape from the LSC via one of its faces. A single-ray Monte Carlo simulation was typically repeated 10³-10⁶ times to have a proper statistical averaging. A stochastic nature of simulations allowed the easy evaluation of various observables and took into consideration additional processes.

B. Results

The present application demonstrates the feasibility of nanocrystal luminescent solar concentrators (NC-LSCs) with no losses to re-absorption over optical paths up to tens of centimeters using giant- or g-CdSe/CdS quantum dots (QDs). Specifically, CdSe/CdS QDs were synthesized with shell thickness, H, up to 5 nm and incorporated into polymethylmethacrylate (PMMA) via a modified version of an industrial cell-cast procedure, which resulted in robust, high-optical-quality QD-polymer nanocomposites. The analysis of steady state and time resolved photoluminescence (PL) demonstrated that QDs with especially thick shells did not show any degradation in their emission efficiencies upon incorporation into the matrix. Further, was shown that because of a large Stokes shift, light emitted by g-QDs propagated within the PMMA matrix for long distances (up to about 20 cm in the experiments disclosed within) without experiencing any re-absorption by the semiconductor material.

Suppression of Re-Absorption in LSCs Based on g-QDs

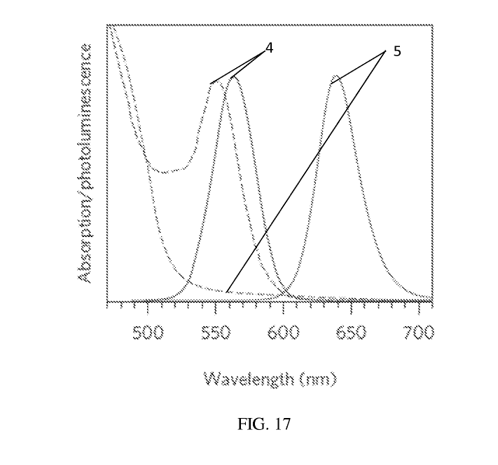

To evaluate the suitability of thick-shell CdSe/CdS QDs for applications in LSCs, the expected optical loss due to re-absorption was analyzed by comparing core/shell structures to reference core-only CdSe QDs. FIG. 17 illustrates absorption and PL spectra of hexane solutions of CdSe QDs with radius of 1.5 nm (FIG. 17: dashed and solid lines 4) and CdSe/CdS core-shell structures (FIG. 17: dashed and solid lines 5) with the same core radius, R₀=1.5 nm, and the shell thickness H=4.5 nm (about 14 monolayers (ML) of CdS). Since in the CdSe/CdS QDs the CdS shell volume was about 50 times larger than that of the CdSe core (about 760 nm³ vs. about 14 nm³), the absorption spectrum was dominated by the CdS shell which completely overwhelmed a much weaker 1S absorption feature of the CdSe core. Due to delocalization of the electron wave function into the CdS shell the PL of CdSe/CdS QDs (640 nm) was red shifted with respect to the emission from the core-only CdSe QDs (560 nm). As a result, CdSe/CdS QDs showed a large “global” Stokes shift (>400 meV), which approached the value defined by the difference in the band-gaps of bulk CdSe and CdS. Importantly, this shift was significantly greater than that of core-only CdSe QDs (about 70 meV).

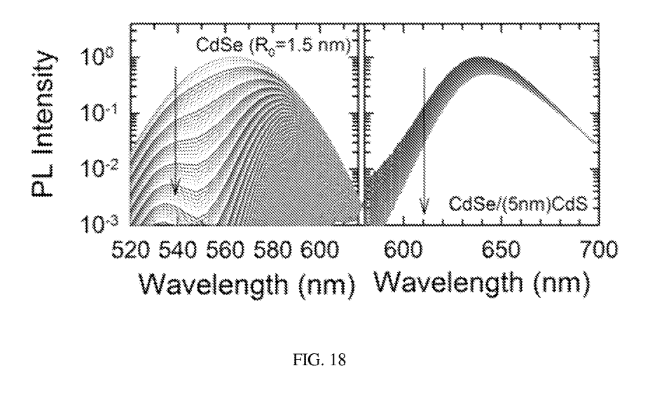

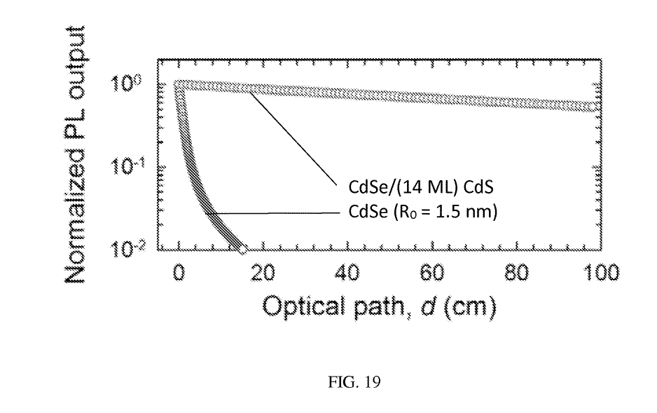

To evaluate the performances of a real LSC, in addition to re-absorption it was necessary to take into account successive stochastic reemission events and respective photoluminescence quantum efficiencies. The effect of re-absorption in giant core/shell and reference core-only QDs can be preliminarily evaluated by neglecting the effect of re-emission and assume a linear propagation path. To evaluate the PL losses during propagation within the LCS, the Lambert-Beer equation was used, with experimentally measured absorption [α(λ)] and emission [I₀(λ)] spectra of QD solutions (FIGS. 18-20): I(λ)=Io(λ)exp[−(α(λ)·d)], where I(λ) is the emission spectrum at the distance d from the emission origin (FIGS. 18 and 19). The calculations indicated that as a result of a significant overlap between emission and absorption spectra, the PL from reference QDs was dramatically attenuated by re-absorption, which was especially pronounced on a bluer side of the emission spectrum. The overall PL intensity drop was very significant even on fairly short distances. The giant CdSe/CdS QDs showed a distinctly different behavior. Because of a large spectral displacement of the emission band with regard to the onset of strong optical absorption, the influence of re-absorption was dramatically reduced. In this case, even for the propagation path as long as one meter, the overall loss of PL intensity was less than 40%.

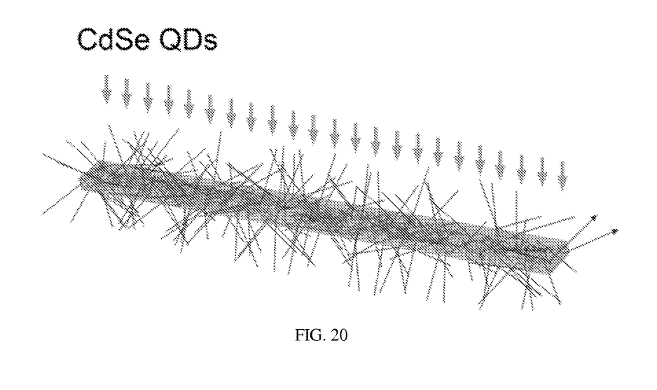

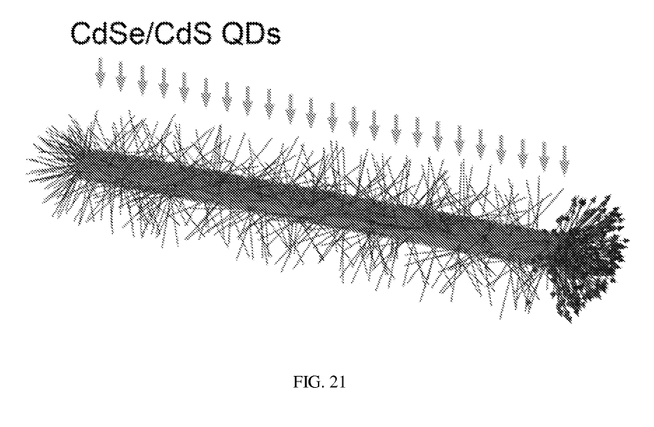

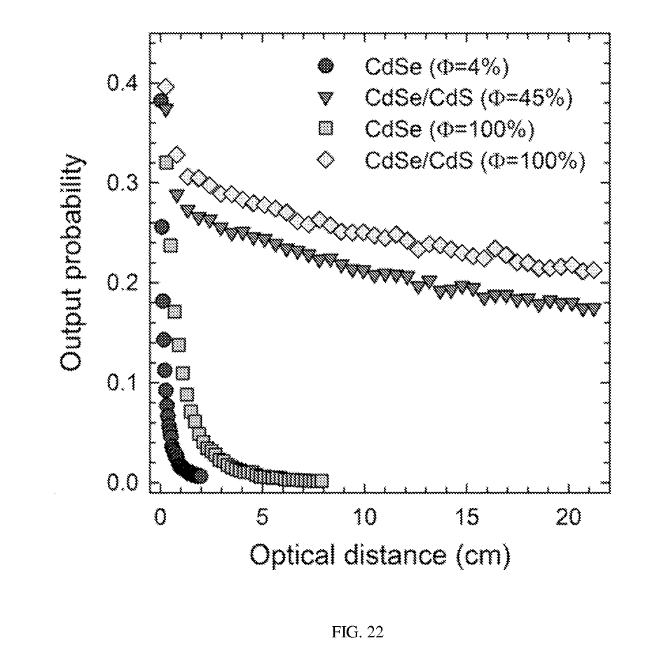

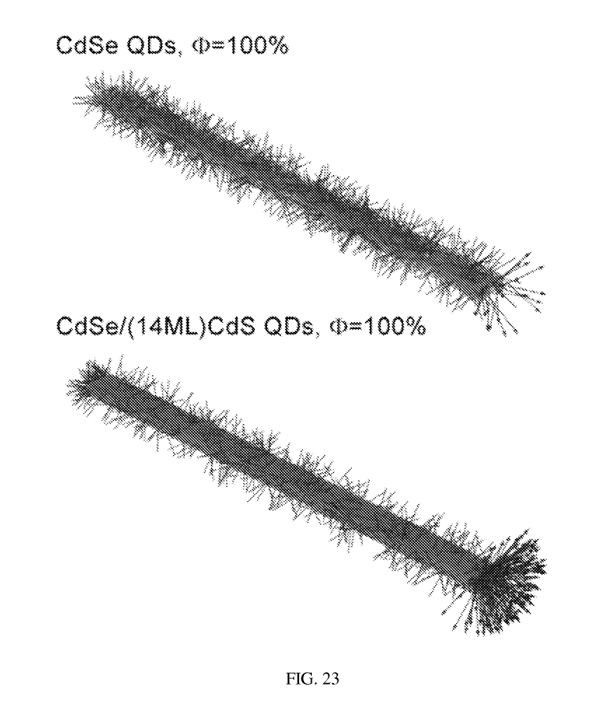

A more accurate evaluation of the optical losses in real devices was also performed, through a Monte Carlo ray tracing simulation of light propagation in LSCs with either core-only CdSe QDs or core/shell CdSe/CdS g-QDs. In the calculations, the QD parameters, device dimensions and refractive index were used that were representative of the real LSCs disclosed herein. Specifically, a rectangular PMMA slab (21.5 cm×1.3 cm×0.5 cm, refractive index n=1.49) was considered, coupled to a photovoltaic cell placed against one of its two smallest faces. Furthermore, it was assumed that the emission quantum efficiencies Φ of core-only CdSe and core/shell CdSe/CdS (H=4.2 nm) QDs were 4% and 45%, respectively. In both cases, to achieve good statistical averaging, the initial number of photons was set to 10 million (FIGS. 20 and 21 present the results for only 1,000 photons, for clarity). In FIGS. 20 and 21, the LSCs are shown uniformly illuminated from the top (thick grey arrows), perpendicularly to the substrate surface (1.3 cm×21.5 cm). Photons reaching the output device face coupled to a PV cell (not shown for clarity) are shown by the smaller arrows. FIG. 20 shows photon propagation within an LSC comprising core-only QDs. As a result of strong re-absorption and low emission efficiency, only 0.5% of the initial photons reached the photovoltaic cell, while 83% were lost to non-radiative recombination and 16.5% escaped from the waveguide through sidewalls and the opposite edge. In contrast, because of greatly reduced re-absorption and increased photoluminescence quantum yield, the number of outgoing photons was increased more than 100-fold for core/shell g-QDs, to 22% of the total number, while 64% escaped from the waveguide and 14% were lost to re-absorption followed by non-radiative recombination (FIG. 21). FIG. 22 shows the probability P_{c} of a photon emitted at a certain distance from the edge reaching the photovoltaic cell in either its original form or as a product of re-emission. These data allowed us to estimate the effective photon collection length L_{c}, defined here as the distance at which P_{c} drops by half. For the core-only QDs, L_{c} was extremely short (13 mm), which severely limited the useful working area of the LSCs. The use of core/shell g-QDs produced a considerable increase in L_{c} (up to about 20 cm), indicating that this type of nanocrystal was indeed suitable for the realization of large-area concentrators. This difference in performance between core-only and core/shell QDs was derived primarily from the difference in their behavior in terms of re-absorption, but not emission. For example, as illustrated by squares and diamonds in FIG. 22, even if it was assumed Φ=100% for both types of QDs, the output of the LSC based on core/shell QDs was still 100 times that of the LSC with core-only QDs. In this case, the poorer performance of conventional QDs was due to strong ‘randomization’ of the light propagation direction, which resulted from frequent re-absorption/re-emission events, leading to a high probability of photon escape from the waveguide (FIG. 23). In FIG. 23, photons reaching the output device face coupled to a PV cell (not shown for clarity) are shown by arrows. In the absence of non-radiative decay channels, all initially generated photons eventually escaped from the LSC. However, stronger re-absorption in the case of core-only QDs vs. core/shell structures led to greater “randomization” of light propagation which resulted in higher escape probability from side walls and hence lower numbers of photons reaching the PV active edge of the LSC. The numerical simulations were carried out using experimental absorption spectra that contain a minor, yet measurable, background due to light scattering. While in the case of core-only CdSe QDs this effect was negligible compared to re-absorption, for g-QDs it provided a more significant relative contribution to the overall PL losses on long optical paths. These estimates suggest great promise for the use of thick-shell QDs in the realization of highly efficient LSCs.

Bulk-Polymerized QD-PMMA Nanocomposites

A practical demonstration of efficient QD-LSCs was not straightforward, as it required effective means for incorporating QDs into high-optical-quality transparent matrices without causing degradation in their photoluminescence efficiency. In these studies the focus was on incorporating QDs into polymethylmethacrylate (PMMA). PMMA exhibits excellent optical properties, high resistance to exposure to ultraviolet light and various chemical treatments, as well as excellent performance in all-weather conditions. PMMA is widely used in construction as a lightweight window material and in optics for fabricating lenses, prisms and optical fibers. Industrial optical-grade PMMA is typically produced through bulk polymerization of methyl methacrylate (MMA) in the presence of thermal radical initiators (mainly azo-compounds and peroxides). Previously, application of this procedure to standard QDs has led to strong QD aggregation, severe deterioration of their surface passivation, and oxidation of the QDs themselves. All these processes were accompanied by dramatic photoluminescence quenching.

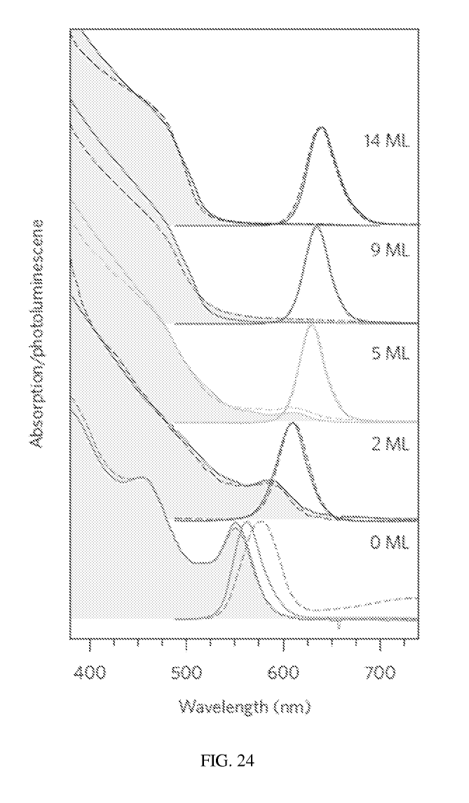

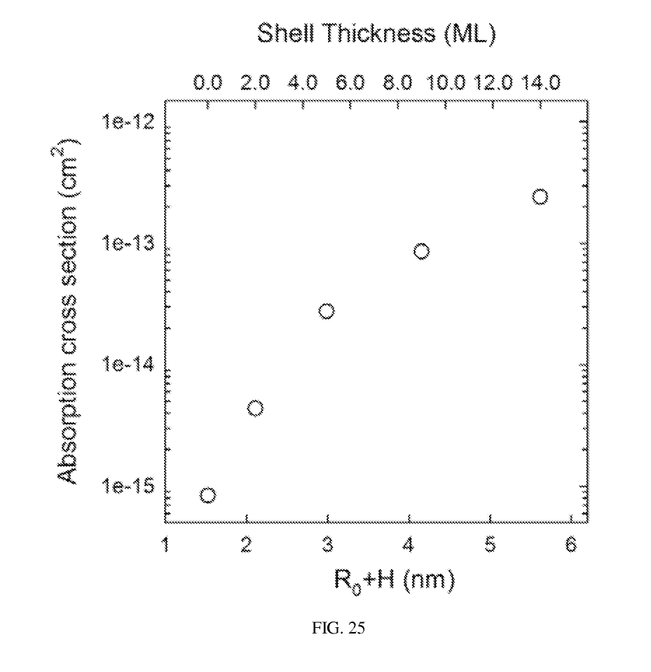

The methodology applied herein was an optimized version of the industrial procedure called cell-casting, modified in such a way as to minimize the interaction between the QDs and the initiator radicals and thereby preserve the optical properties of the QDs upon bulk polymerization of the PMMA matrix. Core/shell CdSe/CdS QDs were studied, with core radius R₀=1.5 nm and several shell thicknesses (H=0, 0.6, 1.5, 2.7 and 4.2 nm, corresponding to 0, 2, 5, 9 and 14 CdS monolayers (MLs or shell layers) respectively), fabricated using a successive ionic layer adsorption and reaction (SILAR) approach. FIG. 24 displays the absorption and photoluminescence spectra of the QD-PMMA nanocomposites and compares them with hexane solutions with the same QD concentration of approximately 0.05 wt %. Analysis of the absolute values of the absorption cross-sections σ at spectral energies above the CdS bandgap indicated a quick increase in σ with increasing H (FIG. 25). These data illustrated the ‘antenna effect’ of a thick CdS shell. For example, the CdSe/CdS QDs with a 4.2 nm shell exhibited over a 100-fold increase in σ at 480 nm compared to core-only CdSe QDs.

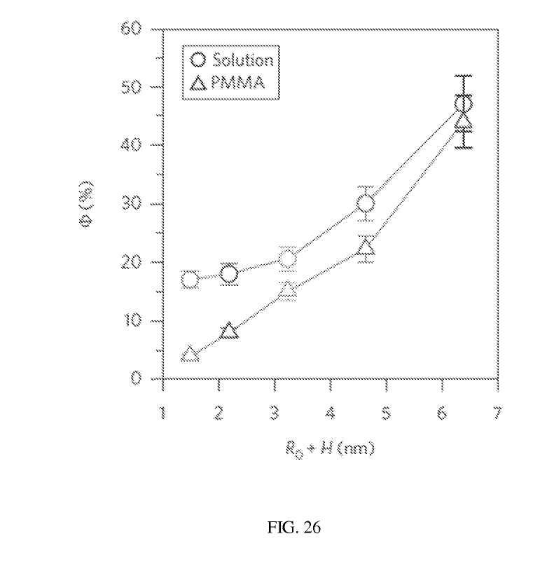

No changes in the position or shape of the absorption and photoluminescence spectra were observed for any of the core/shell QD samples upon incorporation into the PMMA matrix. However, the photoluminescence spectrum of core-only CdSe QDs in PMMA was red shifted compared with the spectrum of the solution and also exhibited a marked shoulder at longer wavelengths, typical of trap emission. The photoluminescence quantum yields of QD-PMMA compositions and their respective solutions are illustrated in FIG. 26. The QDs with larger H featured increasingly higher Φ, up to about 50% for H=4.2 nm.

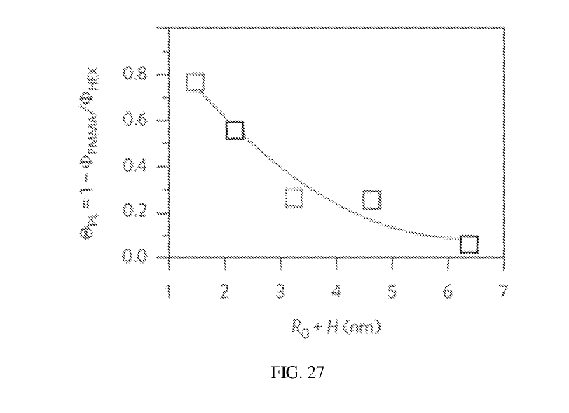

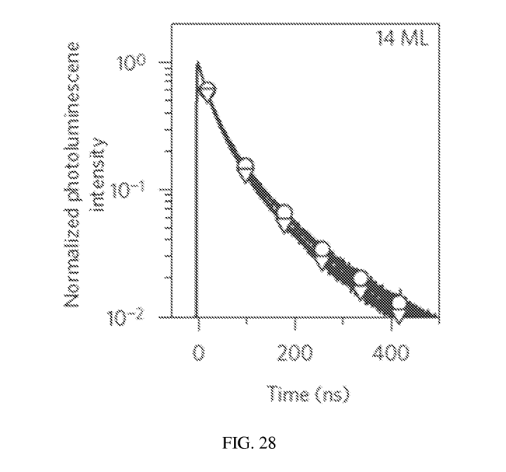

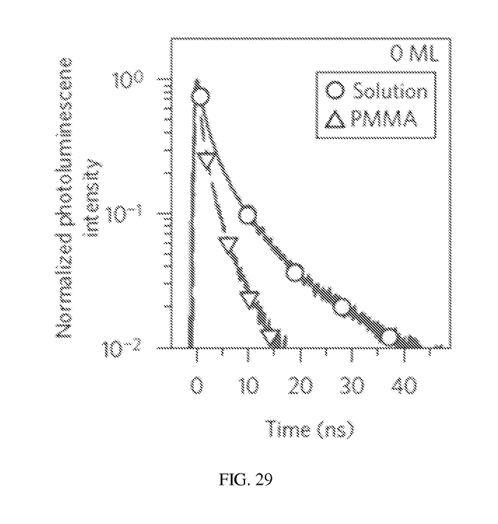

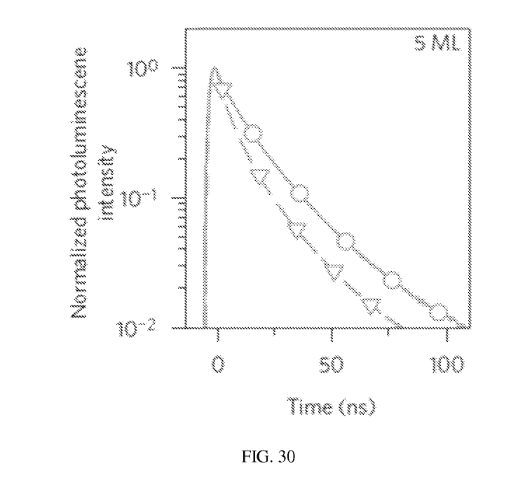

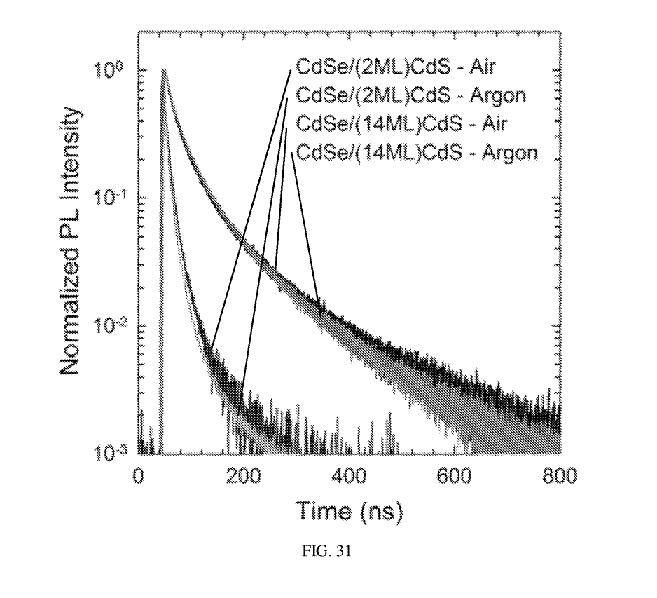

Importantly, these QDs showed essentially no drop in their emission efficiency upon incorporation into PMMA, while thinner shell samples exhibit a significant photoluminescence quenching. The photoluminescence quenching factor (Θ_{PL}=(Φ_{HEX}−Φ_{PMMA})/Φ_{HEX}) is shown in FIG. 27, versus the total QD radius (R=R₀+H). As the shell became thicker, Θ_{PL} decreased from 80% for reference CdSe QDs to only 6% for the thickest-shell CdSe/CdS QDs. The photoluminescence efficiency measurements were corroborated by time-resolved photoluminescence data in FIGS. 28-30. According to the progressively smaller overlap between the electron and hole wavefunctions, the photoluminescence lifetime became longer with increasing shell thickness. Importantly, the photoluminescence dynamics of g-QDs (H=4.2 nm) embedded into PMMA was almost identical to that of the QD hexane solution (FIG. 28). In contrast, QDs with thinner shells exhibited faster photoluminescence decay in PMMA compared to that in solution (FIGS. 28 and 30), indicating an additional contribution from surface-defect-related non-radiative channels that was probably activated by QD exposure to the initiator radicals. These results highlighted the important role of a thick CdS shell, which, in addition to inducing a large Stokes shift, helped preserve the light-emitting properties of the QD core under various chemical treatments. It was also shown that samples synthesized in air showed the same Φ and photoluminescence dynamics as the samples fabricated in argon, which suggested a minor role for oxygen in the photoluminescence quenching process (FIG. 31).

Large-Area LSCs Based on Stokes-Shift-Engineered QDs

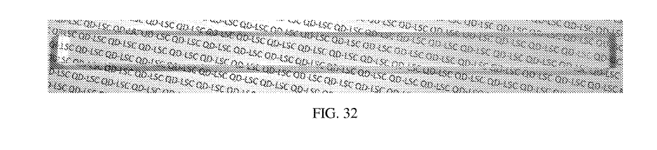

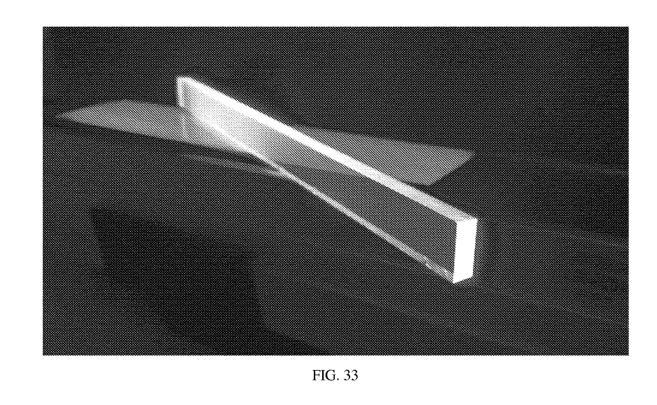

To validate the concept of Stokes-shift engineering for the suppression of re-absorption losses, exemplary large-area QD-LSC prototype devices were fabricated (21.5 cm×1.3 cm×0.5 cm) that utilized CdSe/CdS g-QDs with a 4.2 nm shell. FIGS. 32 and 33 present photographs of one of these devices under room (FIG. 32) and ultraviolet (FIG. 33) illumination; the latter image illustrating how QD photoluminescence excited by ultraviolet radiation on one end of the PMMA slab was guided towards its other end.

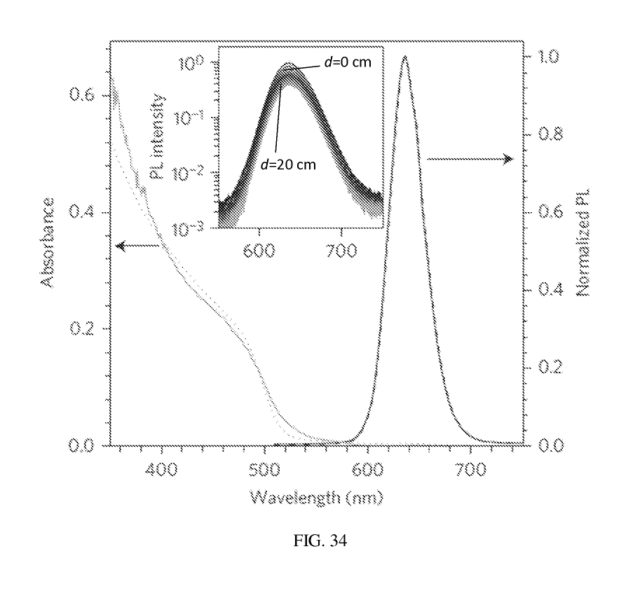

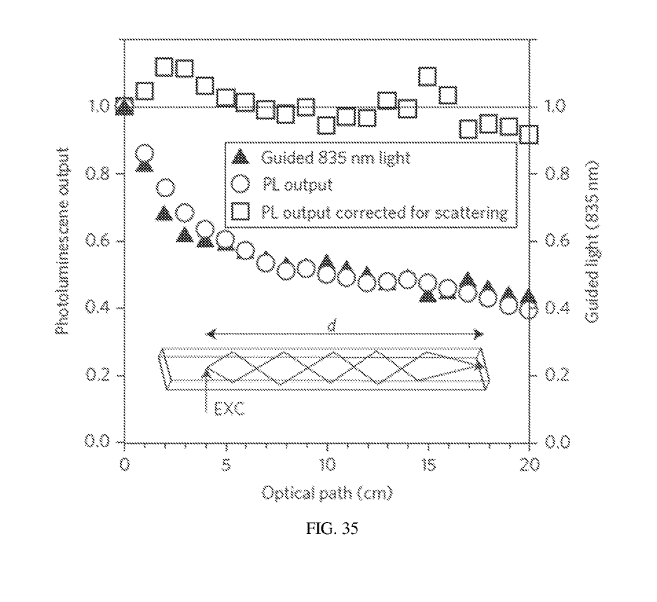

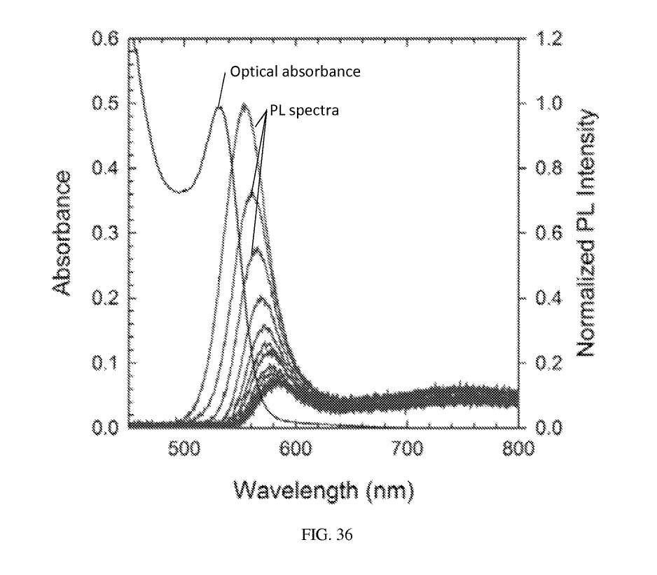

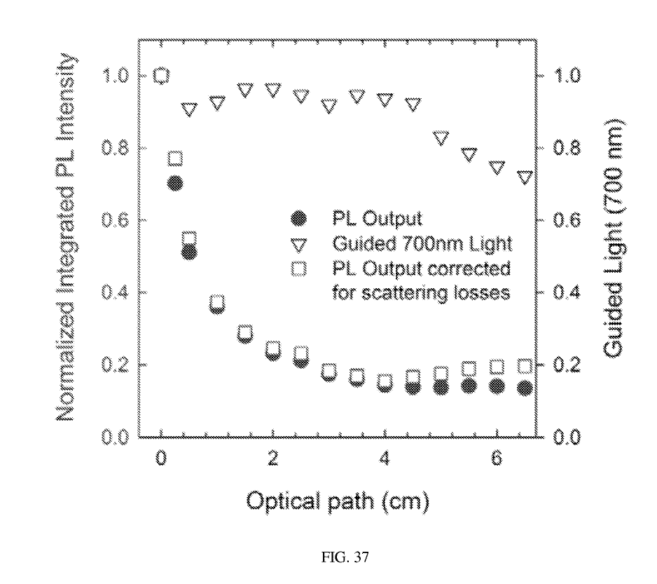

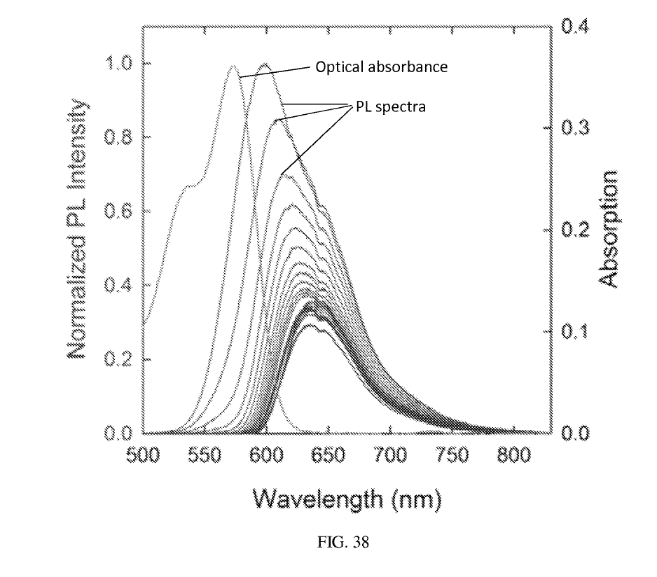

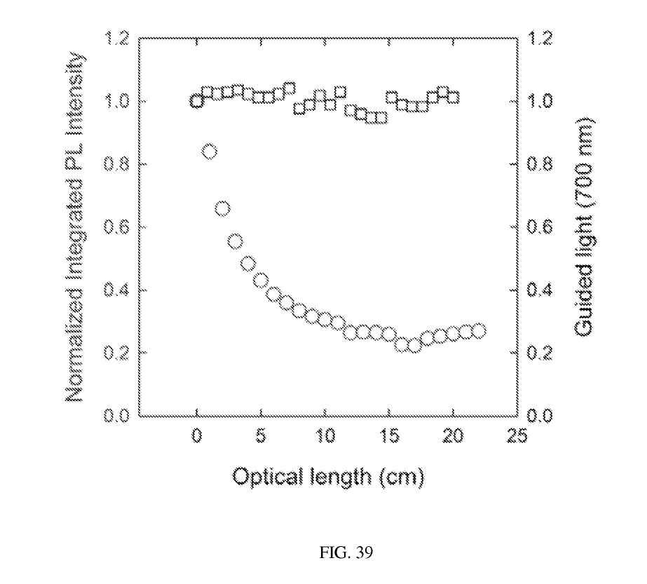

FIG. 34 presents the absorption and emission spectra of the QD-PMMA composite. The absorption spectrum of the slab was nearly identical to that of the solution sample, indicating a small contribution from light scattering. This was a signature of the high optical quality of the QD-PMMA composition. The inset of FIG. 34 illustrates the photoluminescence spectra collected at the edge of the slab for increasing spatial separation d between the excitation spot and the LSC edge. These data indicated a progressive decrease in the photoluminescence intensity with increasing d, which reached about 60% for d=20 cm. If this reduction were due to re-absorption, it would be accompanied by a change in the photoluminescence spectral shape (FIG. 18). However, inspection of the normalized photoluminescence spectra (FIG. 34) suggested that the shape of the photoluminescence band remained unchanged up to d=20 cm, indicating that the observed reduction in the photoluminescence intensity was not due to re-absorption by the QD material, but rather scattering at optical imperfections within the matrix and photon escape through the slab surfaces. Indeed, when the process was repeated for near-infrared scattered laser light at 835 nm, which is not absorbed by the QDs, the observed d-dependence was nearly identical to that measured for photoluminescence (FIG. 35). The ratio between the intensity of QD photoluminescence and near-infrared scattered laser light was almost distance-independent (squares in FIG. 35), which strongly supported the assumption of a negligible role of photoluminescence re-absorption in the QD-PMMA compositions. The advantages of g-QD-based LSCs became especially clear when their performance was compared to that of LSCs based on standard CdSe QDs or traditional organic dyes. The distance-dependent optical losses were also evaluated in a device fabricated using core-only CdSe QDs (FIGS. 36 and 37). FIG. 36 provides the optical absorption and PL spectra (excitation at 405 nm) collected at the edge of the LSC as a function of the distance, d, between the excitation spot and the slab edge. The shape of the PL spectrum changed dramatically with d as a result of strong re-absorption of the band-edge emission. As a result, after 20 mm, the PL spectrum was dominated by a weak trap emission, which, being at longer wavelengths was less affected by re-absorption. In FIG. 37, spectrally integrated PL intensity is illustrated as a function of d (circles; derived from data in FIG. 36) in comparison to the intensity of scattered 700 nm light (triangles). The PL spectra were integrated between 500 and 620 nm in order to minimize the contribution from trap emission. A weak contribution from the trap band was, however, still responsible for the saturation of the integrated PL intensity for d>3 cm. In contrast to the LSC containing CdSe/CdS QDs with a 5 nm shell, the optical losses for the LSC containing core-only CdSe QDs were dominated by re-absorption, while scattering played a minor role. As a result, the PL intensity corrected for scattering losses (squares) showed essentially the same variation with d as the uncorrected data. The measurements indicated that very strong re-absorption leads to about 80% photoluminescence loss on a path length of only 20 mm. In this case, the effect of re-absorption largely overwhelmed losses due to scattering. Importantly, the suppression of re-absorption achieved with Stokes-shift-engineered QDs surpasses that for organic dyes (for example, BASF Lumogen R305) used in state-of-the-art LSCs (FIGS. 38 and 39). FIG. 38 provides the optical absorption and PL spectra (excitation at 473 nm) for a PMMA LSC based on BASF Lumogen R305 collected at the edge of the LSC as a function of the distance, d, between the excitation spot and the slab edge. The shape of the PL spectrum changes dramatically with d as a result of strong re-absorption of emitted light. FIG. 39 provides the spectrally integrated PL intensity as a function of d (circles; derived from data in FIG. 38) in comparison to the intensity of scattered 700 nm light (squares). This industrial grade LSC showed essentially no scattering, which highlighted the dominant role of re-absorption in overall optical losses. However, the photoluminescence intensity still droped by over 75% at d=20 cm, indicating significant losses due to re-absorption. Beside the effect of re-absorption in LSCs embedding ‘conventional’ QDs or dyes, FIGS. 36-39 highlight the importance of eliminating light scattering for reaching efficient solar concentration. With respect to the control, LSCs that show essentially no scattering losses, LSCs based on Stoke-shift engineered QDs were still affected by scattering, which reduced the light output for long optical paths. This can however be minimized through further optimization of polymerization and/or casting conditions by, for example, adjusting the temperature and time of polymer annealing.

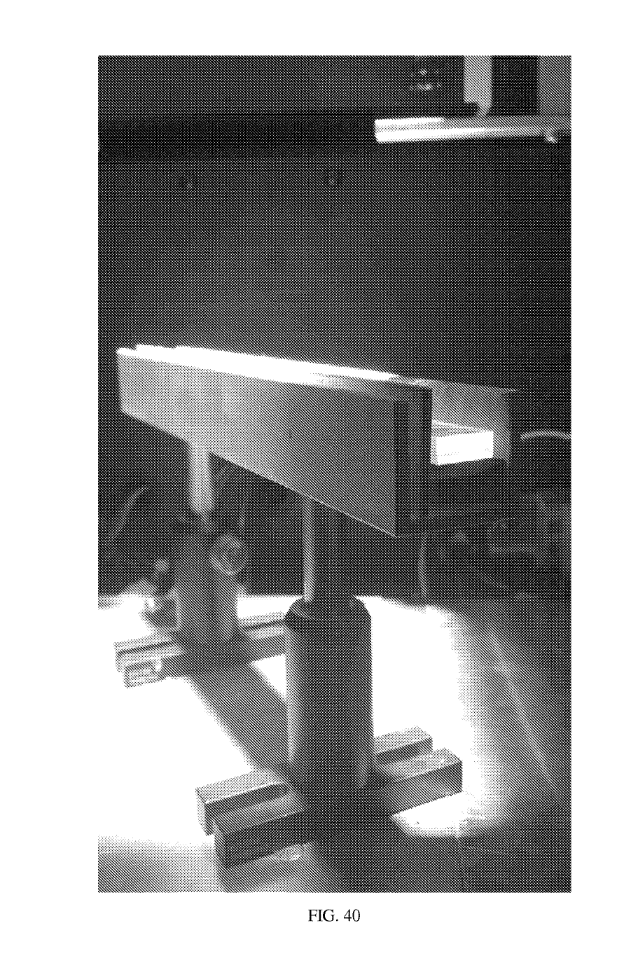

Next the external quantum efficiency and the concentration factor of the g-QD-based LSCs was characterized using the set-up shown in FIG. 40. In these measurements, the light radiated from the edge of the slab (area A_{edge}=1.3 cm×0.5 cm=0.65 cm²) was coupled into a calibrated silicon photodiode. White diffusing reflectors were placed in proximity to the long faces of the LSC to scatter the escaped light back into the waveguide. No reflector was placed at the bottom of the slab or its end opposite to the detector. The concentrator was illuminated perpendicular to its surface (area A_{LSC}=1.3 cm×21.5 cm=27.95 cm²) by a calibrated solar simulator with a power density of I=100 mW cm⁻² (1.5 AM global). The efficiency was calculated using the expression: η=N_{OUT}/N_{IN}, where N_{OUT} is the number of photons collected by the photodiode and N_{IN} is the total number of photons absorbed by the LSC. Based on these measurements, η was calculated to be 10.2%. This result was particularly remarkable as it corresponded to over 1% conversion efficiency per incident photon, achieved using a device that was essentially transparent in the visible spectral region (see FIG. 32), an advantageous property for applications as photovoltaic windows. The effective concentration factor of absorbed light (C) was estimated from C=η(A_{LSC}/A_{edge}) which yielded 4.4. This result provided an important proof of concept for solar light concentration using solid-state LSCs based on engineered QDs. Optimization of such devices could proceed in a number of ways. Specifically, based on the calculations in FIGS. 21 and 22, the approximately 20 cm length of the LSCs is still considerably shorter than the limit imposed by L_{c}, which allows for increasing C by means of a simple increase in the length of the slab. Furthermore, considerable improvements in solar energy conversion are expected with devices where all sides besides the edge equipped with photovoltaic cells are coated with reflecting layers, thereby preventing the escape of photons outside the cone defined by total internal reflection. Finally, there is also room for improvement in the quality of the QDs and, specifically, their emission efficiencies.

Using Stokes-shift-engineered, core/shell CdSe/CdS g-QDs demonstrates the feasibility of using QD-based LSCs with negligible losses to re-absorption of emitted light up to distances of tens of centimeters. The demonstrated approach to Stokes-shift engineering is general and can be extended to smaller-bandgap materials such as lead or tellurium salts to achieve a better match with the absorption spectrum of traditional silicon-based photovoltaic cells and the spectrum of solar radiation. Furthermore, the procedure for QD incorporation into a high quality PMMA matrix is also not QD-material-specific, and can be directly applied to colloidal nanocrystals of various compositions and shapes.

Additionally, for efficient QD-LSCs, the extension of Stokes-shift engineering strategies into the IR range is an important goal. To this end work is underway on a practical implementation of giant-QD ideas in the IR using thick-shell PbSe/CdSe QDs. Spectroscopic measurements of these QDs conducted as a function of increasing shell thickness have revealed typical signatures of a transition to a quasi-type II localization regime which was similar to that observed for giant CdSe/CdS QDs. These observations indicated the feasibility of transferring giant-QD ideas into the IR with newly developed thick-shell PbSe/CdSe QDs.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

1-71. (canceled)

72. A substantially transparent composition, comprising:
a polymer matrix; and
plural, substantially non-aggregated heterostructured nanocrystals substantially homogeneously dispersed in the polymer matrix and separated by a distance greater than an energy transfer distance, the heterostructured nanocrystals comprising an antenna portion and an emitter portion.

73. The composition of claim 72, wherein a hetero-interface between the antenna portion and the emitter portion is a type I, type II or quasi-type II interface.

74. The composition of claim 72, wherein the antenna portion comprises an antenna material with a first band-gap, and the emitter portion comprises an emitter material with a second band-gap, and wherein the first band-gap is larger than the second band-gap.

75. The composition of claim 72, wherein the nanocrystal comprise a core and at least one shell about the core having a shell thickness of greater than 0 to about 6 nanometers.

76. The composition of claim 75 wherein the shell comprises multiple shell layers, the shell having a thickness of from about 3 to about 6 nanometers.

77. The composition of claim 76 wherein the shell comprises from about 5 to about 30 shell layers.

78. The composition of claim 72, wherein the polymer matrix is a polymer matrix transparent to visible light, IR light, UV light, or a combination thereof.

79. The composition of claim 72, wherein the polymer matrix comprises a polymer selected from poly acrylate, poly methacrylate, polyolefin, poly vinyl, epoxy resin, polycarbonate, polyacetate, polyamide, polyurethane, polyketone, polyester, polycyanoacrylate, silicone, polyglycol, polyimide, fluorinated polymer, polycellulose, poly oxazine or combinations thereof.

80. The composition of claim 72, wherein the nanocrystal comprises cadmium sulfide (CdS), cadmium selenide (CdSe), cadmium telluride (CdTe), zinc sulfide (ZnS), zinc selenide (ZnSe), zinc oxide (ZnO), zinc telluride (ZnTe), mercury sulfide (HgS), mercury selenide (HgSe), mercury telluride (HgTe), aluminum nitride (AlN), aluminum sulfide (AlS), aluminum phosphide (AlP), aluminum arsenide (AlAs), aluminum antimonide (AlSb), lead sulfide (PbS), lead selenide (PbSe), lead telluride (PbTe), gallium arsenide (GaAs), gallium nitride (GaN), gallium phosphide (GaP), gallium antimonide (GaSb), indium arsenide (InAs), indium nitride (InN), indium phosphide (InP), indium antimonide (InSb), thallium arsenide (TlAs), thallium nitride (TlN), thallium phosphide (TlP), thallium antimonide (TlSb), zinc cadmium selenide (ZnCdSe), indium gallium nitride (InGaN), indium gallium arsenide (InGaAs), indium gallium phosphide (InGaP), aluminum indium nitride (AlInN), indium aluminum phosphide (InAlP), indium aluminum arsenide (InAlAs), aluminum gallium arsenide (AlGaAs), aluminum gallium phosphide (AlGaP), aluminum indium gallium arsenide (AlInGaAs), aluminum indium gallium nitride (AlInGaN), Si, Ge, Sn, SiGe, SiSn, GeSn, gold (Au), silver (Ag), cobalt (Co), iron (Fe), nickel (Ni), copper (Cu), gallium, silicon, manganese (Mn) or combinations thereof.

81. The composition of claim 80, wherein the nanocrystal has a core/shell structure selected from CdSe/CdS, CdSe/ZnSe, CdSe/ZnS, CdSe/ZnTe, CdSe/CdTe, CdTe/CdSe, CdTe/CdS, CdTe/ZnSe, CdTe/ZnS, CdTe/ZnTe, CdS/ZnSe, CdS/ZnS, CdS/CdTe, CdS/CdSe, PbSe/PbS, PbS/PbSe, PbTe/PbS, PbS/PbTe, PbTe/PbSe, PbSe/PbTe, PbSe/CdSe, CdSe/PbTe, PbS/CdS, CdS/PbS, PbTe/CdTe, CdTe/PbTe, InAs/CdS, InSb/CdS, InP/CdS, InAs/CdSe, InSb/CdSe, InP/CdSe, InAs/ZnSe, InP/ZnSe, InSb/ZnSe, InAs/ZnS, InP/ZnS, InSb/ZnS, Ge/Si, Si/Ge, Sn/Si, Si/Sn, Ge/Sn, or Sn/Ge.

82. The composition of claim 81, wherein:
the nanocrystal is a CdSe/CdS or PbSe/CdSe quantum dot;
the polymer matrix comprises an acrylate polymer; or
the nanocrystal is a CdSe/CdS or PbSe/CdS quantum dot and the polymer matrix comprises an acrylate polymer.

83. The composition of claim 72, wherein the nanocrystal concentration in the polymer matrix is from greater than zero wt % to about 10 wt % relative to the weight of the polymer matrix.

84. A composition substantially transparent to visible light, IR light, UV light, or a combination thereof, the composition, comprising:
a polymer matrix wherein the polymer is selected from poly acrylate, poly methacrylate, polyolefin, poly vinyl, epoxy resin, polycarbonate, polyacetate, polyamide, polyurethane, polyketone, polyester, polycyanoacrylate, silicone, polyglycol, polyimide, fluorinated polymer, polycellulose, poly oxazine or combinations thereof; and
plural, substantially non-aggregated hetero-structured nanocrystals substantially homogeneously dispersed in the polymer matrix at a concentration of from greater than zero wt % to 1 wt % relative to the weight of the polymer matrix such that a nanocrystal emission efficiency drops by less than 10% compared to a quantum dot emission efficiency of nanocrystals dissolved in a solvent, the core/shell structure being selected from CdSe/CdS, CdSe/ZnSe, CdSe/ZnS, CdSe/ZnTe, CdSe/CdTe, CdTe/CdSe, CdTe/CdS, CdTe/ZnSe, CdTe/ZnS, CdTe/ZnTe, CdS/ZnSe, CdS/ZnS, CdS/CdTe, CdS/CdSe, PbSe/PbS, PbS/PbSe, PbTe/PbS, PbS/PbTe, PbTe/PbSe, PbSe/PbTe, PbSe/CdSe, CdSe/PbTe, PbS/CdS, CdS/PbS, PbTe/CdTe, CdTe/PbTe, InAs/CdS, InSb/CdS, InP/CdS, InAs/CdSe, InSb/CdSe, InP/CdSe, InAs/ZnSe, InP/ZnSe, InSb/ZnSe, InAs/ZnS, InP/ZnS, InSb/ZnS, Ge/Si, Si/Ge, Sn/Si, Si/Sn, Ge/Sn, or Sn/Ge, the nanocrystals comprising from 5 to about 30 shell layers and having a shell thickness of from about 3 to about 6 nanometers, the nanocrystals having a global Stokes shift of greater than 200 meV and being separated by a distance greater than an energy transfer distance.

85. A device comprising a composition according to claim 1, wherein the nanocrystals comprise a core and at least one shell about the core having a shell thickness of greater than 0 to about 6 nanometers.

86. The device of claim 29, further comprising a photovoltaic, a reflector, a diffuser, or a combination thereof.

87. The device of claim 29, wherein the device is a window, an optical fiber, or a transparent packaging material.

88. A method for making a composition, comprising:
dispersing hetero-structured nanocrystals in a first amount of a monomer and a first polymerization initiator to form a dispersion of quantum dots in monomer;
heating a second amount of the monomer with a second polymerization initiator at a first temperature to initiate polymerization of the second amount of monomer;
quenching the polymerization of the second amount of monomer, before the polymerization is complete, to form a partially polymerized mixture;
mixing the partially polymerized mixture with the dispersion of nanocrystals in monomer to form a second mixture; and
heating the second mixture at a second temperature to form the composition comprising a polymer matrix with quantum dots dispersed within.

89. The method of claim 88, wherein the first polymerization initiator and second polymerization initiator are independently selected from a peroxide, azo compound, persulfate or organometallic compound.

90. The method of claim 88, wherein the first polymerization initiator has an activation temperature greater than an activation temperature of the second polymerization initiator.

91. The method of claim 88, wherein the first polymerization initiator is lauroyl peroxide and the second polymerization initiator is AIBN.

92. The method of claim 88, wherein the first temperature is from greater than 25° C. to about 150° C., the second temperature is from about 25° C. to about 150° C., or both.

93. The method of claim 88, wherein the first temperature is greater than the second temperature.
